(19) United States
(12) Patent Application Publication
(10) Pub. No.: US 2007/0077449 A1
(43) Pub. Date: Apr. 5, 2007

(54) Hole transport material, layer formed from the hole transport material, organic electroluminescent device, and method of manufacturing the hole transport material

(75) Inventors: Yuji Shinohara, Nagano-ken (JP); Takashi Shinohara, Nagano-ken (JP)

Correspondence Address: OLIFF & BERRIDGE, PLC, P.O. BOX 19928, ALEXANDRIA, VA, 22320, US

(73) Assignee: Seiko Epson Corporation, Tokyo (JP)

(21) Appl. No.: 10/576,248

(22) PCT Filed: Oct. 14, 2004
(86) PCT No.: PCT/JP04/15569

§ 371 Date: Apr. 18, 2006

(30) Foreign Application Priority Data
Oct. 22, 2003 (JP) 2003-362510
Oct. 22, 2003 (JP) 2003-362511

(51) Int. Cl. H01L 51/54; C07B 63/00

(52) U.S. Cl. 428/690; 428/917; 313/504; 313/506; 257/40; 528/380; 528/480; 252/500

(57) ABSTRACT

In an organic EL device, when a voltage is applied across an anode and a cathode, holes are moved in a hole transport layer and electrons are moved in an electron transport layer, and the holes and the electrons are recombined in a light emitting layer. In the light emitting layer, excitons are produced by energy released upon the recombination, and the excitons release energy in the form of fluorescence or emit light when returning to the ground state. The hole transport layer is formed from a hole transport material, in which the amount of nonionic impurities having a molecular weight of 5,000 or less, or the amounts of anionic impurities, cationic impurities and nonionic impurities having a molecular weight of 5,000 or less is or are adjusted to be small, so that the decrease of light-emission luminance of the organic EL device is suppressed.

### TECHNICAL FIELD

The present invention relates to a hole transport material to be used for a layer having the function of transporting holes in an organic electroluminescent device (element), a layer having the function of transporting holes, an organic electroluminescent device and a method of manufacturing the hole transport material.

### BACKGROUND ART

There is known an organic electroluminescent device (hereinafter, referred to as an “organic EL device”). The organic EL device has a structure in which at least one light emitting organic layer (organic electroluminescent layer) is provided between a cathode and an anode. Such an organic EL device can significantly reduce a voltage to be applied as compared with an inorganic EL device. Further, it is also possible to manufacture devices that can provide various luminescent colors.

Currently, in order to obtain higher-performance organic EL devices, various researches are being actively carried out in developments and improvements of materials to be used as well as device structures thereof.

Up to now, organic EL devices that can provide various luminescent colors or organic EL devices that have high luminance and high efficiency have been already developed, and in order to realize their various practical uses such as application to a picture element of a display or a light source, further researches are being carried out.

However, from the viewpoint of practical use, the existing organic EL devices still have a problem in that light-emission luminance thereof is decreased or deteriorated when it is used over a long period of time, and therefore there is a demand for the establishment of technical measures to solve the problem.

As for a method for suppressing the decrease of light-emission luminance of an organic EL device, a method using a high-purity organic compound has been proposed (see Japanese Patent Laid-open No. 2002-175885, for example). Japanese Patent Laid-open No. 2002-175885 discloses an organic EL device, in which the content of a halogen-containing compound (impurities) contained in a material constituting the device is made less than 1,000 ppm, thereby suppressing decrease of light-emission luminance which will occur when it is used over a long period of time.

However, specific indexes of the relationship between the decrease of light-emission luminance in an organic EL device and the kinds of impurities contained in the constituent materials to be used and their amounts contained therein have not yet been established. Thus, further researches are being made toward realizing the practical use.

### DISCLOSURE OF INVENTION

It is therefore an object of the present invention to provide a hole transport material, a layer and an organic electroluminescent device which can suppress the decrease of light-emission luminance in an organic EL device, and a method of manufacturing the hole transport material.

In order to achieve the object, the present invention is directed to a hole transport material to be used for a layer having the function of transporting holes in an organic EL device, the hole transport material being characterized in that when the hole transport material is dissolved or dispersed in a liquid so that its concentration becomes 2.0 wt %, the liquid contains nonionic impurities having a molecular weight of 5,000 or less, but an amount of the nonionic impurities contained therein is 40 ppm or less.

According to the invention described above, it is possible to provide a hole transport material that can suppress the decrease of light-emission luminance of an organic EL device.

In the hole transport material described above, it is preferred that the nonionic impurities mainly include those which are formed and/or mixed when synthesizing the hole transport material. By eliminating such nonionic impurities, it becomes possible to provide a hole transport material that can more reliably suppress the decrease of light-emission luminance of an organic EL device.

Further, in the hole transport material described above, it is preferred that the nonionic impurities include at least one of polyalcohol and heterocyclic aromatic compound. All of these nonionic impurities have extremely high reactivity with the hole transport material, so that they are particularly apt to deteriorate the hole transport material. Therefore, the elimination of such nonionic impurities makes it possible to provide a hole transport material which can more reliably suppress the decrease of light-emission luminance of the organic EL device.

Further, it is also preferred that the hole transport material includes at least one selected from the group comprising thiophene/styrenesulfonate-based compounds, arylcycloalkane-based compounds, arylamine-based compounds, phenylenediamine-based compounds, carbazole-based compounds, stilbene-based compounds, oxazole-based compounds, triphenylmethane-based compounds, pyrazoline-based compounds, benzine-based compounds, triazole-based compounds, imidazole-based compounds, oxadiazole-based compounds, anthracene-based compounds, fluorenone-based compounds, aniline-based compounds, silane-based compounds, thiophene-based compounds, pyrrole-based compounds, florene-based compounds, porphyrin-based compounds, quinacridon-based compounds, phthalocyanine-based compounds, naphthalocyanine-based compounds, and benzidine-based compounds. This is because all of these compounds have especially high hole transporting ability.

Furthermore, it is also preferred that the hold transport material contains a poly(thiophene/styrenesulfonate)-based compound as its major component, and wherein when the hole transport material is dissolved or dispersed in a liquid so that its concentration thereof becomes 2.0 wt %, the liquid contains nonionic impurities having a molecular weight of 5,000 or less, but an amount of the nonionic impurities contained therein is six or less with respect to 1,000 styrene units. This also makes it possible to provide a hole transport material which can more reliably suppress the decrease of light-emission luminance of the organic EL device.

In this case, it is preferred that the number of the nonionic impurities and the number of the styrene units are measured from areas of peaks in a spectrum obtained by an ¹H-NMR analysis for the liquid. This makes it possible to measure the amount of the nonionic impurities in the hole transport material easily and accurately in a shot time.

Further, in the hole transport material described above, it is preferred that the poly(thiophene/styrenesulfonate)-based compound has a weight ratio of thiopene to styrenesulfonate which is in the range of 1:5 to 1:50. This makes it possible to achieve a higher hole transporting ability.

Furthermore, in the hole transport material described above, it is preferred that the volume resistivity of the hole transport material is 10 Ω·cm or larger. This makes it possible to provide an organic EL device having higher light emitting efficiency.

Another aspect of the present is also directed to a layer having the function of transporting holes and provided in an organic EL device, wherein the layer is characterized by containing nonionic impurities having a molecular weight of 5, 000 or less, but an amount of the nonionic impurities is 2,000 ppm or less. By using such a layer, it is possible to provide an organic EL device that can suppress the decrease of light-emission luminance.

Further, the present invention is also directed to a layer having the function of transporting holes and provided in an organic electroluminescent device, the layer being formed from a hole transport material containing poly(thiophene/styrenesulfonate)-based compound as its major component, wherein the layer contains nonionic impurities having a molecular weight of 5,000 or less, but an amount of the nonionic impurities contained therein is six or less with respect to 1000 styrene units. This also makes it possible to provide an organic EL device that can suppress the decrease of light-emission luminance.

In the layer mentioned above, it is preferred that the number of the nonionic impurities and the number of the styrene units are measured from areas of peaks in a spectrum obtained by an ¹H-NMR analysis for the layer. This makes it possible to measure the amount of the nonionic impurities in the hole transport layer easily and accurately in a shot time.

The present invention is also directed to a layer having the function of transporting holes and provided in an organic electroluminescent device, the layer being characterized by being formed from a material containing the hole transport material described in claim 1 as its major component. By using such a layer, it is possible to provide an organic EL device that can suppress the decrease of light-emission luminance.

Other aspect of the present invention is directed to an organic electroluminescent device having a layer described above. Such an organic EL device can exhibit a high performance.

Yet other aspect of the present invention is directed to a method of manufacturing a hole transport material described in claim 1, the method comprising the steps of: preparing a solution or dispersion liquid in which the hole transport material is dissolved or dispersed in a solvent or a dispersion medium; separating or eliminating nonionic impurities having a molecular weight of 5,000 or less using an eliminating means for separating or eliminating the nonionic impurities; and removing the solvent or dispersion medium from the liquid, thereby refining the hole transport material.

According to the manufacturing method of the invention described above, it possible to eliminate the nonionic impurities in the hole transport layer easily and accurately in a shot time.

In this method, it is preferred that the eliminating means includes an ultrafiltration membrane. This makes it possible to eliminate target nonionic impurities efficiently and reliably only by appropriately selecting the kind of an ultrafiltration membrane to be used.

In addition to the above, the present invention is also directed to a hole transport material to be used for a layer having the function of transporting holes in an organic EL device, the hole transport material being characterized in that when the hole transport material is dissolved or dispersed in a liquid so that its concentration becomes 2.0 wt %, the liquid contains anionic impurities, cationic impurities and nonionic impurities having a molecular weight of 5,000 or less, but amounts of the anionic impurities, cationic impurities and nonionic impurities contained therein are 30 ppm or less, 30 ppm or less and 40 ppm or less, respectively.

According to the invention described above, it is possible to suppress the decrease of light-emission luminance of an organic EL device.

In the hole transport material of this invention, it is preferred that when the hole transport material is dissolved or dispersed in a liquid so that the concentration thereof becomes 2.0 wt %, the total amount of the anionic impurities, cationic impurities and nonionic impurities contained therein is 90 ppm or less. This makes it possible to more reliably suppress the decrease of light-emission luminance of an organic EL device.

In the hole transport material described above, it is preferred that the anionic impurities include at least one of sulfate ion, formate ion, oxalate ion and acetate ion. All of these ions have extremely high reactivity with the hole transport material, so that they are particularly apt to deteriorate the hole transport material. Therefore, the elimination of such ions makes it possible to provide a hole transport material which can more reliably suppress the decrease of light-emission luminance of the organic EL device.

Further, in the hole transport material described above, it is preferred that the cationic impurities mainly include metal ion. By eliminating such a metal ion, it is possible to obtain a hole transport material which can more reliably suppress the decrease of light-emission luminance of the organic EL device.

In this case, it is preferred that the metal ion includes at least one kind of metal ions of metals belonging to Ia group, IIa group, VIa group, VIIa group, VIII group and Ib group of the periodic table. By eliminating these metal ions, the effect of suppressing the decrease of light-emission luminance of the organic EL device is especially and conspicuously exhibited.

Further, in the hole transport material described above, it is preferred that the nonionic impurities mainly include those which are formed and/or mixed when synthesizing the hole transport material. By eliminating such nonionic impurities, it is possible to obtain a hole transport material which can more reliably suppress the decrease of light-emission luminance of the organic EL device.

Further, it is also preferred that the nonionic impurities include at least one of polyalcohol and heterocyclic aromatic compound. All of these nonionic impurities have extremely high reactivity with the hole transport material, so that they are particularly apt to deteriorate the hole transport material. Therefore, the elimination of such nonionic impurities makes it possible to obtain a hole transport material which can more reliably suppress the decrease of light-emission luminance of the organic EL device.

Furthermore, in the hole transport material described above, it is preferred that the volume resistivity of the hole transport material is 10 Ω·cm or larger. This makes it possible to provide an organic EL element having higher light emitting efficiency.

Moreover, in the present invention, it is preferred that the hole transport material is selected from the group comprising thiophene/styrenesulfonic acid-based compounds, arylcycloalkane-based compounds, arylamine-based compounds, phenylenediamine-based compounds, carbazole-based compounds, stilbene-based compounds, oxazole-based compounds, triphenylmethane-based compounds, pyrazoline-based compounds, benzine-based compounds, triazole-based compounds, imidazole-based compounds, oxadiazole-based compounds, anthracene-based compounds, fluorenone-based compounds, aniline-based compounds, silane-based compounds, thiophene-based compounds, pyrrole-based compounds, florene-based compounds, porphyrin-based compounds, quinacridon-based compounds, phthalocyanine-based compounds, naphthalocyanine-based compounds, and benzidine-based compounds. All of these compounds have high hole transport ability.

Moreover, in the present invention, it is also preferred that the hole transport material contains a poly(thiophene/styrenesulfonic acid)-based compound as its major component. This compound is preferable since it has especially high hole transport ability.

In this case, it is preferred that the poly(thiophene/styrenesulfonic acid) -based compound has a weight ratio of thiophene to styrenesulfonic acid which is in the range of 1:5 to 1:50. This makes it possible to provide the hole transport material having a higher hole transporting ability.

Another aspect of the present invention is directed to a layer having the function of transporting holes and is provided in an organic electroluminescent device, wherein the layer is characterized by containing anionic impurities, cationic impurities and nonionic impurities having a molecular weight of 5,000 or less, but amounts of the anionic impurities, cationic impurities and nonionic impurities are 1,500 ppm or less, 1,500 ppm or less and 2,000 ppm or less, respectively. By using such a layer, it is possible to provide an organic EL device that can suppress the decrease of light-emission luminance.

In the layer of this invention, it is preferred that the total amount of the anionic impurities, cationic impurities and nonionic impurities is 4,500 ppm or less. This makes it possible to more reliably suppress the decrease of light-emission luminance in the organic EL device.

The present invention is also directed to a layer which has the function of transporting holes and is provided in an organic electroluminescent device, the layer being characterized by being formed of a material containing the hole transport material of the present invention described above as its major component. By using such a layer, it is possible to provide an organic EL device that can suppress the decrease of light-emission luminance.

Yet another aspect of the present invention is directed to an organic EL device which is characterized by having a layer of the present invention described above. Such an organic EL device can exhibit a higher performance.

Other aspect of the present invention is directed to a method of manufacturing a hole transport material according to the invention described above, the method comprising the steps of:

preparing a solution or a dispersion liquid in which the hole transport material is dissolved or dispersed in a solvent or a dispersion medium;

separating or eliminating anionic impurities, cationic impurities and nonionic impurities having a molecular weight of 5,000 or less using a first elimination means for separating or eliminating the anionic impurities, a second elimination means for separating or eliminating the cationic impurities, and a third elimination means for separating or eliminating the nonionic impurities at substantially the same time or successively; and

removing the solvent or dispersion medium from the liquid, thereby refining the hole transport material.

According to the manufacturing method of the invention described above, it is possible to eliminate the nonionic impurities from a hole transport material with relatively ease and in a relatively short period of time.

In this manufacturing method, it is preferred that the third elimination means includes an ultrafiltration membrane. This makes it possible to eliminate target nonionic impurities reliably and efficiently only by appropriately selecting the kind of ultrafiltration membrane to be used.

These and other objects, structures and results of the present invention will be apparent more clearly when the following detailed description of the preferred embodiments is considered taken in conjunction with the appended drawings.

### BRIEF DESCRIPTION OF DRAWING

FIG. 1 is a cross-sectional view which shows an example of an organic EL device.

### BEST MODE FOR CARRYING OUT THE INVENTION

First, before discussing the details of the hole transport material, the layer, the organic electroluminescent device, and the method of manufacturing such a hole transport material of the present invention, an example of an organic electroluminescent device (organic EL device) which has a hole transport layer formed using the hole transport material of the present invention will be described.

<Organic EL Device>

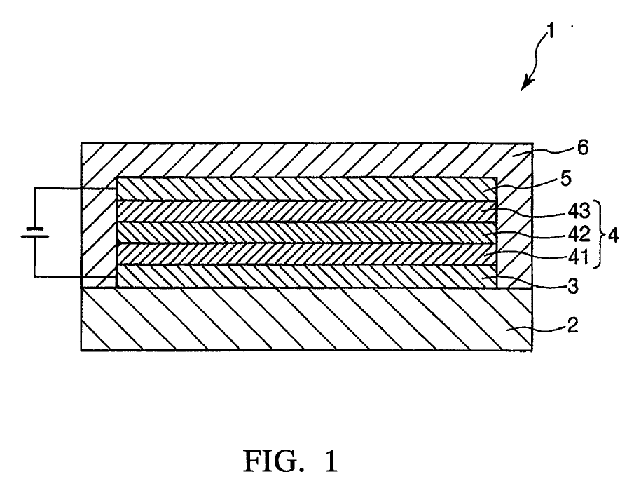

FIG. 1 is a cross-sectional view which shows an example of an organic EL device.

An organic EL device 1 shown in FIG. 1 includes a transparent substrate 2, an anode 3 provided on the substrate 2, an organic EL layer 4 provided on the anode 3, a cathode 5 provided on the organic EL layer 4 and a protection layer 6 provided so as to cover these layers 3, 4 and 5.

The substrate 2 serves as a support of the organic EL device 1, and the layers described above are formed on the substrate 2.

As a constituent material of the substrate 2, a material having a light transmitting property and a good optical property can be used.

Examples of such a material include various resin materials such as polyethylene terephthalate, polyethylene naphthalate, polypropylene, cycloolefin polymer, polyamide, polyether sulfone, polymethyl methacrylate, polycarbonate, and polyarylate, various glass materials, and the like. These materials can be used singly or in combination of two or more of them.

The thickness of the substrate 2 is not limited to any specific value, but is preferably in the range of about 0.1 to 30 mm, more preferably in the range of about 0.1 to 10 mm.

The anode 3 is an electrode which injects holes into the organic EL layer 4 (that is, into a hole transport layer 41 described later). Further, this anode 3 is made substantially transparent (which includes colorless and transparent, colored and transparent, or translucent) so that light emission from the organic EL layer 4 (that is, from a light emitting layer 42 described later) can be visually identified.

From such a viewpoint, a material having a high work function, excellent conductivity and a light transmitting property is preferably used as a constituent material of the anode 3 (hereinafter, referred to as “anode material”).

Examples of such an anode material include oxides such as ITO (Indium Tin Oxide), SnO₂, Sb-containing SnO₂ and Al-containing ZnO, Au, Pt, Ag, Cu, and alloys containing two or more of them. These materials can be used singly or in combination of two or more of them.

The thickness of the anode 3 is not limited to any specific value, but is preferably in the range of about 10 to 200 nm, more preferably in the range of about 50 to 150 nm. If the thickness of the anode 3 is too thin, there is a fear that a function as the anode 3 is not sufficiently exhibited. On the other hand, if the anode 3 is too thick, there is a fear that light transmittance is significantly lowered depending on the kind of anode material used, or the like, thus resulting in an organic EL device that can not be suitably used for practical use.

It is to be noted that conductive resins such as polythiophene, polypyrrole, and the like can also be used for the anode material, for example.

On the other hand, the cathode 5 is an electrode which injects electrons into the organic EL layer 4 (that is, into an electron transport layer 43 described later).

As a constituent material of the cathode 5 (hereinafter, referred to as “cathode material”), a material having a low work function is preferably used.

Examples of such a cathode material include Li, Mg, Ca, Sr, La, Ce, Er, Eu, Sc, Y, Yb, Ag, Cu, Al, Cs, Rb, and alloys containing two or more of them. These materials can be used singly or in combination of two or more of them.

Particularly, in a case where an alloy is used as the cathode material, an alloy containing a stable metallic element such as Ag, Al, or Cu, specifically an alloy such as MgAg, AlLi, or CuLi is preferably used. The use of such an alloy as the cathode material makes it possible to improve the electron injection efficiency and stability of the cathode 5.

The thickness of the cathode 5 is preferably in the range of about 1 nm to 1 μm, more preferably in the range of about 100 to 400 nm. If the thickness of the cathode 5 is too thin, there is a fear that a function as the cathode 5 is not sufficiently exhibited. On the other hand, if the cathode 5 is too thick, there is a fear that the light emitting efficiency of the organic EL device 1 is lowered.

Between the anode 3 and the cathode 5, there is provided the organic EL layer 4. The organic EL layer 4 includes the hole transport layer 41, the light emitting layer 42, and the electron transport layer 43. These layers 41, 42 and 43 are formed on the anode 3 in this order.

The hole transport layer 41 has the function of transporting holes, which are injected from the anode 3, to the light emitting layer 42.

Any material can be employed as a constituent material of the hole transport layer 41 (hereinafter, referred to as “hole transport material”) so long as it has hole transport ability. However, it is preferred that the constituent material of the hole transport layer 41 is formed of a compound having a conjugated system. This is because a compound having a conjugated system can extremely smoothly transport holes due to a property resulting from its unique spread of an electron cloud, so that such a compound has especially excellent hole transport ability.

Further, the hole transport material to be used may be in either of the solid form, semisolid form or liquid form at room temperature. Since such a hole transport material in either of the above-mentioned forms is easy to handle, a hole transport layer 41 can be easily and reliably formed, thus it is possible to obtain a higher performance organic EL device 1.

In the present invention, a high molecule (polymer or prepolymer) containing a compound (monomer) listed below in a main chain or a side chain thereof is used as a hole transport material. Such a high molecule is used singly or in combination of two or more of them.

Examples of such a compound (monomer) include: thiophene/styrenesulfonic acid-based compounds such as 3,4-ethylenedioxythiophene/styrenesulfonic acid; arylcycloalkane-based compounds such as 1,1-bis(4-di-para-triaminophenyl)cyclohexane and 1,1′-bis(4-di-para-tolylaminophenyl)-4-phenyl-cyclohexane; arylamine-based compounds such as 4,4′,4″-trimethyltriphenylamine, N,N,N′,N′-tetraphenyl-1,1′-biphenyl-4,4′-diamine, N,N′-diphenyl-N,N′-bis(3-methylphenyl)-1,1′-biphenyl-4,4′-diamine(TPD1), N,N′-diphenyl-N,N′-bis(4-methoxyphenyl)-1,1′-biphenyl-4,4′-diamine(TPD2), N,N,N′,N′-tetrakis(4-methoxyphenyl)-1,1′-biphenyl-4,4′-diamine(TPD3), N,N′-di(1-naphthyl)-N,N′-diphenyl-1,1′-biphenyl-4,4′-diamine(α-NPD), and TPTE; phenylenediamine-based compounds such as N,N,N′,N′-tetraphenyl-para-phenylenediamine, N,N,N′,N′-tetra(para-tolyl)-para-phenylenediamine, and N,N,N′,N′-tetra(meta-tolyl)-meta-phenylenediamine(PDA); carbazole-based compounds such as carbazole, N-isopropylcarbazole, and N-phenylcarbazole; stilbene-based compounds such as stilbene, and 4-di-para-tolylaminostilbene; oxazole-based compounds such as OₓZ; triphenylmethane-based compounds such as triphenylmethane, and m-MTDATA; pyrazoline-based compounds such as 1-phenyl-3-(para-dimethylaminophenyl)pyrazoline; benzine(cyclohexadiene)-based compounds; triazole-based compounds such as triazole; imidazole-based compounds such as imidazole; oxadiazole-based compounds such as 1,3,4-oxadiazole, and 2,5-di(4-dimethylaminophenyl)-1,3,4-oxadiazole; anthracene-based compounds such as anthracene, and 9-(4-diethylaminostyryl)anthracene; fluorenone-based compounds such as fluorenone, 2,4,7-trinitro-9-fluorenone, and 2,7-bis(2-hydroxy-3-(2-chlorophenylcarbamoyl)-1-naphthylazo)fluorenone; aniline-based compounds such as polyaniline; silane-based compounds; thiophene-based compounds such as polythiophene, and poly(thiophenevinylene); pyrrole-based compounds such as poly(2,2′-thienylpyrrole), and 1,4-dithioketo-3,6-diphenyl-pyrrolo-(3,4-c)pyrrolopyrrole; florene-based compounds such as florene; porphyrin-based compounds such as porphyrin, and metal tetraphenylporphyrin; quinacridon-based compounds such as quinacridon; metallic or non-metallic phthalocyanine-based compounds such as phthalocyanine, copper phthalocyanine, tetra(t-butyl)copper phthalocyanine, and iron phthalqcyanine; metallic or non-metallic naphthalocyanine-based compounds such as copper naphthalocyanine, vanadyl naphthalocyanine, and monochloro gallium naphthalocyanine; and benzidine-based compounds such as N,N′-di(naphthalene-1-yl)-N,N′-diphenyl-benzidine and N,N,N′,N′-tetraphenylbenzidine. All of high molecules containing these compounds have high hole transport ability.

In this regard, it is to be noted that in this specification a high molecule means a compound having a molecular weight of 5,000 or more.

Among these high molecules, a hole transport material containing as its major component poly(thiophene/styrenesulfonic acid)-based compound such as poly(3,4-ethylenedioxythiophene/styrenesulfonic acid) (hereinafter, referred to as “PEDT/PSS”), which is 3,4-ethylenedioxythiophene/styrenesulfonic acid polymer, is particularly preferable. Poly(thiophene/styrenesulfonic acid)-based compounds have especially high hole transport ability.

Further, it is preferred that the poly(thiophene/styrenesulfonic acid)-based compounds preferably have a weight ratio of thiophene to styrenesulfonic acid in the range of about 1:5 to 1:50, and more preferably in the range of about 1:10 to 1:25. By setting the weight ratio of thiophene to styrenesulfonic acid to a value within the above range, it is possible to obtain poly(thiophene/styrenesulfonic acid)-based compounds having higher hole transport ability.

Further, the hole transport layer 41 is formed of such a high molecule as its major component, but a low molecule.(monomer or oligomer) containing the above-mentioned compounds therein may be contained in the hole transport layer 41.

Furthermore, in such a hole transport material, it is preferred that the volume resistivity thereof is 10 Ω·cm or larger, and more preferably 10² Ω·cm or larger. This makes it possible to provide an organic EL device 1 having higher light emitting efficiency.

The thickness of the hole transport layer 41 is not limited to any specific value, but is preferably in the range of about 10 to 150 nm, more preferably in the range of about 50 to 100 nm. If the thickness of the hole transport layer 41 is too thin, there is a fear that a pin hole is produced. On the other hand, if the thickness of the hole transport layer 41 is too thick, there is a fear that the transmittance of the hole transport layer 41 is lowered so that the chromaticity (hue) of luminescent color of the organic EL device 1 is changed.

The hole transport material according to the present invention is particularly useful to form such a relatively thin hole transport layer 41.

The electron transport layer 43 has the function of transporting electrons, which are injected from the cathode 5, to the light emitting layer 42.

Examples of a constituent material of the electron transport layer 43 (an electron transport material) include: benzene-based compounds (starburst-based compounds) such as 1,3,5-tris[(3-phenyl-6-tri-fluoromethyl)quinoxaline-2-yl]benzene (TPQ1), and 1,3,5-tris[(3-(4-t-butylphenyl)-6-trisfluoromethyl)quinoxaline-2-yl]benzene (TPQ2); naphthalene-based compounds such as naphthalene; phenanthrene-based compounds such as phenanthrene; chrysene-based compounds such as chrysene; perylene-based compounds such as perylene; anthracene-based compounds such as anthracene; pyrene-based compounds such as pyrene; acridine-based compounds such as acridine; stilbene-based compounds such as stilbene; thiophene-based compounds such as BBOT; butadiene-based compounds such as butadiene; coumarin-based compounds such as coumarin; quinoline-based compounds such as quinoline; bistyryl-based compounds such as bistyryl; pyrazine-based compounds such as pyrazine and distyrylpyrazine; quinoxaline-based compounds such as quinoxaline; benzoquinone-based compounds such as benzoquinone, and 2,5-diphenyl-para-benzoquinone; naphthoquinone-based compounds such as naphthoquinone; anthraquinone-based compounds such as anthraquinone; oxadiazole-based compounds such as oxadiazole, 2-(4-biphenylyl)-5-(4-t-butylphenyl)-1,3,4-oxadiazole (PBD), BMD, BND, BDD, and BAPD; triazole-based compounds such as triazole, and 3,4,5-triphenyl-1,2,4-triazole; oxazole-based compounds; anthrone-based compounds such as anthrone; fluorenone-based compounds such as fluorenone, and 1,3,8 -trinitro-fluorenone (TNF); diphenoquinone-based compounds such as diphenoquinone, and MBDQ; stilbenequinone-based compounds such as stilbenequinone, and MBSQ; anthraquinodimethane-based compounds; thiopyran dioxide-based compounds; fluorenylidenemethane-based compounds; diphenyldicyanoethylene-based compounds; florene-based compounds such as florene; metallic or non-metallic phthalocyanine-based compounds such as phthalocyanine, copper phthalocyanine, and iron phthalocyanine; and various metal complexes such as 8-hydroxyquinoline aluminum (Alq₃), and complexes having benzooxazole or benzothiazole as a ligand.

The above-mentioned compounds that can be used as an electron transport material may be used singly or in combination of two or more of them.

The thickness of the electron transport layer 43 is not limited to any specific value, but is preferably in the range of about 1 to 100 nm, more preferably in the range of about 20 to 50 nm. If the thickness of the electron transport layer 43 is too thin, there is a fear that a pin hole is produced, causing a short-circuit. On the other hand, if the electron transport layer 43 is too thick, there is a fear that the value of resistance becomes high.

When a current flows between the anode 3 and the cathode 5 (that is, a voltage is applied across the anode 3 and the cathode 5), holes are moved in the hole transport layer 41 and electrons are moved in the electron transport layer 43, and the holes and the electrons are then recombined in the light emitting layer 42. Then, in the light emitting layer 42, excitons are produced by energy released upon the recombination, and the excitons release energy (in the form of fluorescence or phosphorescence) or emit light when returning to the ground state.

Any material can be used as a constituent material of the light emitting layer 42 (a light emitting material) so long as it can provide a field where holes can be injected from the anode 3 and electrons can be injected from the cathode 5 during the application of a voltage to allow the holes and the electrons to be recombined.

Such light emitting materials include various low-molecular light emitting materials and various high-molecular light emitting materials (which will be mentioned below). These materials can be used singly or in combination of two or more of them.

In this regard, it is to be noted that the use of a low-molecular light emitting material makes it possible to obtain a dense light emitting layer 42, thereby improving the light emitting efficiency of the light emitting layer 42. Further, since such a high-molecular light emitting material is relatively easily dissolved in a solvent, it is possible to form the light emitting layer 42 easily by means of various application methods such as an ink-jet printing method and the like. Furthermore, if the low-molecular light emitting material and the high-molecular light emitting material are used together, it is possible to obtain the synergistic effect resulted from the effect of the low-molecular light emitting material and the effect of the high-molecular light emitting material. That is, it is possible to obtain an effect that a dense light emitting layer 42 having an excellent light emitting efficiency can be easily formed by means of various application methods such as an ink-jet printing method and the like.

Examples of such a low-molecular light emitting material include: benzene-based compounds such as distyrylbenzene (DSB), and diaminodistyrylbenzene (DADSB); naphthalene-based compounds such as naphthalene and Nile red; phenanthrene-based compounds such as phenanthrene; chrysene-based compounds such as chrysene and 6-nitrochrysene; perylene-based compounds such as perylene, and N,N′-bis(2,5-di-t-butylphenyl)-3,4,9,10-perylene-di-carboxyimide (BPPC); coronene-based compounds such as coronene; anthracene-based compounds such as anthracene, and bisstyrylanthracene; pyrene-based compounds such as pyrene; pyran-based compounds such as 4-(di-cyanomethylene)-2-methyl-6-(para-dimethylaminostyryl)-4H-pyran (DCM); acridine-based compounds such as acridine; stilbene-based compounds such as stilbene; thiophene-based compounds such as 2,5-dibenzooxazolethiophene; benzooxazole-based compounds such as benzooxazole; benzoimidazole-based compounds such as benzoimidazole; benzothiazole-based compounds such as 2,2′-(para-phenylenedivinylene)-bisbenzothiazole; butadiene-based compounds such as bistyryl(1,4-diphenyl-1,3-butadiene), and tetraphenylbutadiene; naphthalimide-based compounds such as naphthalimide; coumarin-based compounds such as coumarin; perynone-based compounds such as perynone; oxadiazole-based compounds such as oxadiazole; aldazine-based compounds; cyclopentadiene-based compounds such as 1,2,3,4,5-pentaphenyl-1,3-cyclopentadiene (PPCP); quinacridone-based compounds such as quinacridone and quinacridone red; pyridine-based compounds such as pyrrolopyridine, and thiadiazolopyridine; spiro compounds such as 2,2′,7,7′-tetraphenyl-9,9′-spirobifluorene; metallic or non-metallic phthalocyanine-based compounds such as phthalocyanine (H₂Pc), and copper phthalocyanine; florene-based compounds such as florene; and various metallic complexes such as 8-hydroxyquinoline aluminum (Alq₃), tris(4-methyl-8-quinolinolate) aluminum(III) (Almq₃), 8-hydroxyquinoline zinc (Znq₂), (1,10-phenanthroline)-tris-(4,4,4-trifluoro-1-(2-thienyl)-butane-1,3-dionate) europium(III) (Eu(TTA) 3(phen)), fac-tris(2-phenylpyridine) iridium (Ir(ppy)₃), and 2,3,7,8,12,13,17,18-octaethyl-21H, 23H-porphin platinum(II).

Examples of a high-molecular light emitting material include polyacetylene-based compounds such as trans-type polyacetylene, cis-type polyacetylene, poly(di-phenylacetylene) (PDPA), and poly(alkyl, phenylacetylene) (PAPA); polyparaphenylenevinylene-based compounds such as poly(para-phenylenevinylene) (PPV), poly(2,5-dialkoxy-para-phenylenevinylene) (RO-PPV), cyano-substituted-poly(para-phenylenevinylene) (CN-PPV), poly(2-dimethyloctylsilyl-para-phenylenevinylene) (DMOS-PPV), and poly(2-methoxy-5-(2′-ethylhexoxy)-para-phenylenevinylene) (MEH-PPV); polythiophene-based compounds such as poly(3-alkylthiophene) (PAT), and poly(oxypropylene)triol (POPT); polyfluorene-based compounds such as poly(9,9-dialkylfluorene) (PDAF), α,ω-bis[N,N′-di(methylphenyl)aminophenyl]-poly[9,9-bis(2-ethylhexyl)fluorene-2,7-diyl] (PF2/6am4), poly(9,9-dioctyl-2, 7-divinylenefluorenyl)-alt-co(anthracene-9,10-diyl); polyparaphenylene-based compounds such as poly(para-phenylene) (PPP), and poly(1,5-dialkoxy-para-phenylene) (RO-PPP); polycarbazole-based compounds such as poly(N-vinylcarbazole) (PVK); and polysilane-based compounds such as poly(methylphenylsilane) (PMPS), poly(naphthylphenylsilane) (PNPS), and poly(biphenylylphenylsilane) (PBPS).

The thickness of the light emitting layer 42 is not limited to any specific value, but is preferably in the range of about 10 to 150 nm, more preferably in the range of about 50 to 100 nm. By setting the thickness of the light emitting layer to a value within the above range, recombination of holes and electrons efficiently occurs, thereby enabling the light emitting efficiency of the light emitting layer 42 to be further improved.

Although, in the present embodiment, each of the light emitting layer 42, the hole transport layer 41 and the electron transport layer 43 is separately provided, they may be formed into a hole-transportable light emitting layer which combines the hole transport layer 41 with the light emitting layer 42 or an electron-transportable light emitting layer which combines the electron transport layer 43 with the light emitting layer 42. In this case, an area in the vicinity of the interface between the hole-transportable light emitting layer and the electron transport layer 43 or an area in the vicinity of the interface between the electron-transportable light emitting layer and the hole transport layer 41 functions as the light emitting layer 42.

Further, in a case where the hole-transportable light emitting layer is used, holes injected from an anode into the hole-transportable light emitting layer are trapped by the electron transport layer, and in a case where the electron-transportable light emitting layer is used, electrons injected from a cathode into the electron-transportable light emitting layer are trapped in the electron-transportable light emitting layer. In both cases, there is an advantage that the recombination efficiency of holes and electrons can be improved.

Furthermore, between the adjacent layers in the layers 3,4 and 5, any additional layer may be provided according to its purpose. For example, a hole injecting layer may be provided between the hole transport layer 41 and the anode 3, or an electron injecting layer may be provided between the electron transport layer 43 and the cathode 5. In such a case where the organic EL device 1 is provided with the hole injecting layer, the hole transport material of the present invention may be employed for the hole injecting layer. On the other hand, in a case where the organic EL device 1 is provided with the electron injecting layer, not only the electron transport material mentioned above but also alkali halide such as LiF, and the like may be employed for the electron injecting layer.

The protection layer 6 is provided so as to cover the layers 3, 4 and 5 constituting the organic EL device 1. This protection layer 6 has the function of hermetically sealing the layers 3, 4 and 5 constituting the organic EL device 1 to shut off oxygen and moisture. By providing such a protection layer 6, it is possible to obtain the effect of improving the reliability of the organic EL device and the effect of preventing the alteration and deterioration of the organic EL device 1.

Examples of a constituent material of the protection layer 6 include Al, Au, Cr, Nb, Ta and Ti, alloys containing them, silicon oxide, various resin materials, and the like. In this regard, it is to be noted that in a case where a conductive material is used as a constituent material of the protection layer 6, it is preferred that an insulating film is provided between the protection layer 6 and each of the layers 3, 4 and 5 to prevent a short circuit therebetween, if necessary.

This organic EL device 1 can be used for a display, for example, but it can also be used for various optical purposes such as a light source and the like.

In a case where the organic EL device 1 is applied to a display, the drive system thereof is not particularly limited, and either of an active matrix system or a passive matrix system may be employed.

The organic EL device 1 as described above can be manufactured in the following manner, for example.

<1> First, the substrate 2 is prepared, and the anode 3 is then formed on the substrate 2.

The anode 3 can be formed by, for example, chemical vapor deposition (CVD) such as plasma CVD, thermal CVD, and laser CVD, vacuum deposition, sputtering, dry plating such as ion plating, wet plating such as electrolytic plating, immersion plating, and electroless plating, thermal spraying, a sol-gel method, a MOD method, bonding of a metallic foil, or the like.

<2> Next, the hole transport layer 41 is formed on the anode 3.

The hole transport layer 41 can be formed by, for example, applying a hole transport layer material (material for forming a hole transport layer), obtained by dissolving the hole transport material as mentioned above in a solvent or dispersing it in a dispersion medium, on the anode 3.

In the application of the hole transport layer material, various application methods such as a spin coating method, a casting method, a micro gravure coating method, a gravure coating method, a bar coating method, a roll coating method, a wire-bar coating method, a dip coating method, a spray coating method, a screen printing method, a flexographic printing method, an offset printing method, an ink-jet printing method, and the like can be employed. According to such an application method, it is possible to relatively easily form the hole transport layer 41.

Examples of a solvent in which the hole transport material is to be dissolved or a dispersion medium in which the hole transport material is to be dispersed include: inorganic solvents such as nitric acid, sulfuric acid, ammonia, hydrogen peroxide, water, carbon disulfide, carbon tetrachloride, and ethylene carbonate; and various organic solvents such as ketone-based solvents e.g., methyl ethyl ketone (MEK), acetone, diethyl ketone, methyl isobutyl ketone (MIBK), methyl isopropyl ketone (MIPK), and cyclohexanone, alcohol-based solvents e.g., methanol, ethanol, isopropanol, ethylene glycol, diethylene glycol (DEG), and glycerol, ether-based solvents e.g., diethyl ether, diisopropyl ether, 1,2-dimethoxy ethane (DME), 1,4-dioxane, tetrahydrofuran (THF), tetrahydropyran (THP), anisole, diethylene glycol dimethyl ether (diglyme), and diethylene glycol ethyl ether (Carbitol), cellosolve-based solvents e.g., methyl cellosolve, ethyl cellosolve, and phenyl cellosolve, aliphatic hydrocarbon-based solvents e.g, hexane, pentane, heptane, and cyclohexane, aromatic hydrocarbon-based solvents e.g., toluene, xylene, and benzene, aromatic heterocyclic compound-based solvents e.g., pyridine, pyrazine, furan, pyrrole, thiophene, and methyl pyrrolidone, amide-based solvents e.g., N,N-dimethylformamide (DMF), and N,N-dimethylacetamide (DMA), halogen compound-based solvents e.g., dichloromethane, chloroform, and 1,2 -dichloroethane, ester-based solvents e.g., ethyl acetate, methyl acetate and ethyl formate, sulfur compound-based solvents e.g., dimethyl sulfoxide (DMSO) and sulfolane, nitrile-based solvents e.g., acetonitrile, propionitrile, and acrylonitrile, organic acid-based solvents e.g., formic acid, acetic acid, trichloroacetic acid, and trifluoroacetic acid, and mixed solvents containing them.

If necessary, an obtained coating may be subjected to heat treatment, for example, in the atmosphere or an inert atmosphere or under a reduced pressure (or a vacuum). This makes it possible to dry the coating (removal of a solvent or a dispersion medium) or polymerize the hole transport material, for example. In this regard, it is to be noted that the coating may be dried without heat treatment.

Further, in a case where a low-molecular hole transport material is used, a binder (high-molecular binder) may be added to the hole transport layer material, if necessary.

As a binder, one which does not extremely inhibit charge transport and has a low absorptivity for visible radiation is preferably used. Specifically, examples of such a binder include polyethylene oxide, polyvinylidene fluoride, polycarbonate, polyacrylate, polymethyl acrylate, polymethyl methacrylate, polystyrene, polyvinyl chloride, polysiloxane, and the like, and they can be used singly or in combination of two or more of them. Alternatively, the high-molecular hole transport material as mentioned above may be used for the binder.

It is to be noted that in a case where a low-molecular hole transport material is used, the hole transport layer 41 may also be formed by, for example, vacuum deposition or the like.

<3> Next, the light emitting layer 42 is formed on the hole transport layer 41.

The light emitting layer 42 can be formed in the same manner as the hole transport layer 41. Namely, the light emitting layer 42 can be formed using the light emitting material mentioned above in a manner as described above with reference to the hole transport layer 41.

<4> Next, the electron transport layer 43 is formed on the light emitting layer 42.

The electron transport layer 43 can be formed in the same manner as the hole transport layer 41. Namely, the electron transport layer 43 can be formed using the electron transport material mentioned above in a manner as described above with reference to the hole transport layer 41.

<5> Next, the cathode 5 is formed on the electron transport layer 43.

The cathode 5 can be formed by, for example, vacuum deposition, sputtering., bonding of a metallic foil, or the like.

<6> Next, the protection layer 6 is formed so as to cover the anode 3, the organic EL layer 4 and the cathode 5.

The protection layer 6 can be formed (provided) by, for example, bonding a box-like protection cover constituted of the material as mentioned above by the use of various curable resins (adhesives).

As for the curable resins, all of thermosetting resins, photocurable resins, reactive curable resins, and anaerobic curable resins can be used.

The organic EL device 1 is manufactured through these processes as described above.

The features of the present invention reside in a layer having the function of transporting holes in an organic EL device, and a hole transport material. Hereinafter, such features (characteristics) will be described.

### First Embodiment

In order to suppress the decrease of light-emission luminance of the organic EL device, the present inventors have made extensive researches and studies for all the layers constituting the organic EL device, and in particular they have paid their attentions to a layer having the function of transporting holes.

As a result, the present inventors have found that the decrease of light-emission luminance of the organic EL device can be effectively suppressed by controlling an amount of impurities contained in the layer having the function of transporting holes, especially the amount of nonionic impurities having a molecular weight of 5,000 or less (hereinafter, simply referred to as “nonionic impurities”) to within a predetermined amount, leading to the completion of the present invention. In the specification, this will be described as a first embodiment.

As described above, there are known a hole injection layer and the like besides a hole transport layer as a layer having the function of transporting holes, but hereinafter, only the hole transport layer will be descried as a representative of such layers.

If the amount of the nonionic impurities contained in the hole transport layer is large, a structural change (decomposition and the like, for example) of the hole transport material occurs due to the nonionic impurities acting as a trigger, resulting in the deterioration of the hole transport layer with the elapse of time. Further, when such nonionic impurities trap the holes (electrons), excess heat is generated due to the resistance of the impurities, also resulting in the deterioration of the hole transport layer with the elapse of time. This is one of the factors that causes the decrease of the light-emission luminance of the organic EL device.

On the other hand, in a hole transport layer in which an amount of nonionic impurities contained therein is controlled to within a small range (that is, a range indicated below), it is possible to prevent or suppress the structural change of the hole transport material from occurring, thereby enabling to suppress the decrease of light-emission luminance of the organic EL device. As a result, it is possible to provide an organic EL device that can maintain excellent light emitting properties for a long period of time.

Specifically, in the present invention, the amount of the nonionic impurities contained in the hole transport layer is controlled to be 2,000 ppm or less, preferably 1,000 ppm or less, and more preferably 250 ppm or less.

In this regard, it is to be noted that in a case where the nonionic impurities contain plural kinds of nonionic impurities therein, the above-mentioned “amount” refers to the total amount of all the impurities contained therein (that is, inclusive sum of all the kinds of nonionic impurities).

Further, in a case where the hole transport layer is constituted from a hole transport material containing a poly(thiophene/styrenesulfonate)-based compound as its major component, it is preferred that the amount of the nonionic impurities contained in the hole transport layer is set or adjusted with the number of the nonionic impurities with respect to the number of the styrene units contained therein. This makes it possible to set or adjust the amount of the nonionic impurities to within the above-mentioned range more accurately.

In more details, the number of the nonionic impurities contained in the hole transport layer is preferably 6 or less with respect to 1,000 styrene units, more preferably 3 or less, and even more preferably 1 or less.

In this case, the number of the nonionic impurities and the number of the styrene units contained in the hole transport layer may be measured by various methods, but it is preferred that they are measured from areas of peaks in a spectrum obtained by an ¹H-NMR analysis. According to this method, it is possible to measure the number of the nonionic impurities and the number of the styrene units contained in the hole transport layer easily in a short time.

Although various causes can be mentioned on why nonionic impurities are mixed into the hole transport layer, one of the main causes seems to be that substances (especially, solvent) added to synthesize the hole transport material, which is a major component of the hole transport layer, and substances produced in the course of the synthesis (such as unexpectedly synthesized substances or resolvents, for example) are not sufficiently eliminated.

Examples of such substances (that is, nonionic impurities) include one or more kinds of multiple alcohol such as diethylene glycol (DEG), ethylene glycol and glycerin, and aromatic heterocyclic compound such as N-methyl-pyrrolidone. In particular, it is highly likely that these substances cause a structural change of the hole transport material with the elapse of time. Therefore, by eliminating these substances, it is possible to reliably prevent the deterioration of the hole transport layer from occurring with the elapse of time.

As for the nonionic impurities to be eliminated, impurities formed and/or mixed when the hole transport material is synthesized can be mentioned. Further, substances produced due to the decomposition of the hole transport material when the hole transport material is preserved can be also mentioned.

For example, as for the nonionic impurities contained in the hole transport layer which is formed from the hole transport material mainly constituted of a poly(thiophene/styrenesulfonate)-based compound, ethylene glycol can be mentioned.

The hole transport layer containing a small amount of nonionic impurities can be formed reliably by using such a hole transport material as described below, for example.

Namely, it is preferable to use such a hole transport material that when the hole transport material is dissolved or dispersed in a liquid so that its concentration becomes 2.0 wt %, an amount of nonionic impurities contained in the liquid is preferably 40 ppm or less, more preferably 20 ppm or less, and even more preferably 5 ppm or less.

Further, in the case of a hole transport material containing a poly(thiophene/styrenesulfonate)-based compound as its major component, it is preferred that the amount of the nonionic impurities contained in the hole transport layer is set or adjusted with the number of the nonionic impurities with respect to the number of the styrene units contained therein due to the reasons described above.

In this case, it is also preferred that the numbers of the nonionic impurities and the styrene units contained in the hole transport layer are measured based on areas of peaks derived from them in a spectrum obtained by an ¹H-NMR analysis.

Specifically, the number of the nonionic impurities contained in the hole transport layer is preferably 6 or less with respect to 1,000 styrene units, more preferably 3 or less, and even more preferably 1 or less. This makes it possible to reliably adjust the amount of the nonionic impurities contained in the hole transport material to within the above-mentioned range.

Further, by forming a hole transport layer using such a hole transport material, it becomes possible to reliably adjust the amount of the nonionic impurities contained in the hole transport layer to within the above-mentioned range.

In this regard, however, it is to be noted that it is not always necessary to form the hole transport layer using such a hole transport material, and it is sufficient if the amount of the nonionic impurities contained in the finally obtained hole transport layer lies within the above-mentioned range.

Such a hole transport material can be manufactured or refined as follows. Hereinbelow, a description will be made with regard to the method for refining (manufacturing) the hole transport material according to the present invention.

The method for refining the hole transport material according to the present invention is carried out by eliminating nonionic impurities from a solution or a dispersion liquid in which the hole transport material is dissolved or dispersed by means of an elimination means for separating or eliminating nonionic impurities, and then removing the a solvent or dispersion medium.

As for the elimination means, an ultrafiltration membrane, a filter, an adsorbent, and a permeable membrane can be mentioned, which can be used singly or in combination of two or more of them.

Among these elimination means, the ultrafiltration membrane is preferably employed. By using the ultrafiltration membrane as an elimination means, it is possible to relatively easily eliminate nonionic impurities from a solution or a dispersion liquid in a short period of time. Further, since the ultrafiltration membrane has an excellent separation property for various substances according to molecular weights thereof, only by appropriately selecting the kind of ultrafiltration membrane to be used, target nonionic impurities can be efficiently and reliably eliminated.

For this reason, by employing the ultrafiltration membrane as the elimination means, the elimination of nonionic impurities can be carried out with particularly high accuracy.

Hereinafter, a detailed description will be made with regard to the representative case in which as for the method for eliminating nonionic impurities the ultrafiltration method using such an ultrafiltration membrane is employed.

In the ultrafiltration method, a solution for refinement obtained by dissolving a hole transport material in a solvent or a dispersion liquid for refinement obtained by dispersing a hole transport material in a dispersion medium (hereinafter, these are referred to as solution for refinements) is passed through an ultrafiltration membrane to separate and eliminate nonionic impurities from the solution for refinement, and then the solvent (dispersion medium) is removed to thereby refine the hole transport material. In this way, the amount of the nonionic impurities contained in the hole transport material is adjusted to within the above-mentioned range.

When the solution for refinement is prepared, the same solvents (or dispersion medium) that have been mentioned with reference to the method for manufacturing the organic EL device 1 (process of forming the hole transport layer 41) can be used.

As for an ultrafiltration membrane used in the utrafiltration method, an aperture diameter thereof may be selected depending on a molecular weight of nonionic impurities to be eliminated.

The rate at the time when the solution for refinement is passed through an ultrafiltration membrane (that is, “liquid passage rate”) is not limited to any specific value, but is preferably in the range of about 1 to 100 mL/min, more preferably in the range of about 1 to 20 mL/min. By setting the liquid passage rate of the solution for refinement to a value within the above range, it is possible to more efficiently carry out the elimination of nonionic impurities.

Further, the temperature of the solution for refinement (that is, “solution temperature”) is also not limited to any specific value, but it is preferred that the temperature is as high as possible within the range that does not interfere with the operation for eliminating nonionic impurities. Namely, the solution temperature is preferably in the range of about 0 to 80° C., more preferably in the range of about 10 to 25° C. By setting the solution temperature to a value within the above range, it is possible to more efficiently carry out the elimination of nonionic impurities.

In this case, the solution for refinement may be passed through an ultrafiltration membrane not only once but also two or more times, or it may also be passed through different kinds of ultrafiltration membranes. Further, these filtering operations may be carried out in combination. By doing so, it is possible to more efficiently eliminate nonionic impurities.

Further, the solution for refinement after being refined may be directly employed to manufacture the organic EL device without removing the solvent (or the dispersion medium), or may also be employed to manufacture the organic EL device after being concentrated or diluted.

### Second Embodiment

In addition to the above, the present inventors have also found that the decrease of light-emission luminance of the organic EL device can be effectively suppressed by controlling amounts of anionic impurities, cationic impurities and nonionic impurities having a molecular weight of 5,000 or less (hereinafter, simply referred to as “nonionic impurities”) to within predetermined amounts, respectively, leading to the completion of the present invention. In the specification, this will be described as a second embodiment.

If the amounts of impurities such as nonionic impurities, anionic impurities and cationic impurities contained in the hole transport layer are large, a reaction between the hole transport material and the impurities occurs, or a structural change (decomposition and the like, for example) of the hole transport material occurs due to the impurities acting as a trigger, resulting in the deterioration of the hole transport layer with the elapse of time. Further, when such nonionic impurities trap the holes (electrons), excess heat is generated due to the resistance of the impurities, also resulting in the deterioration of the hole transport layer with the elapse of time. This is one of the factors that causes the decrease of the light-emission luminance of the organic EL device.

Further, in a hole transport layer in which amounts of anionic impurities, cationic impurities and nonionic impurities contained therein are controlled to within a small range described below, it is possible to prevent or suppress the structural change of the hole transport material from occurring, thereby enabling to suppress the decrease of light-emission luminance of the organic EL device. As a result, it is also possible to provide an organic EL device that can maintain excellent light emitting properties for a long period of time.

In this case, it is preferred that the amounts of such impurities in the hole transport layer are controlled to be as small as possible. For example, the total amount of these impurities is preferably 4,500 ppm or less, more preferably 2,500 ppm or less, and even more preferably 1,000 ppm or less. This makes it possible to more reliably suppress the decrease of light-emission luminance of the organic EL device. In addition, it is more preferred that the amount of each impurities contained in the hole transport layer is evenly reduced.

Specifically, in the present invention, the amount of each of the anionic impurities, cationic impurities and nonionic impurities contained in the hole transport layer is adjusted to be 1,500 ppm or less, 1,500 ppm or less, and 2,000 ppm or less, respectively. This makes it possible to more reliably suppress the decrease of light-emission luminance of the organic EL device 1.

In this regard, it is to be noted that in a case where each of the anionic impurities, cationic impurities and nonionic impurities contains plural kinds of impurities therein, the above-mentioned “amount” refers to the total amount of all impurities contained therein (that is, inclusive sum of all the kinds of impurities).

In particular, the amount of the anionic impurities contained in the hole transport layer is preferably 1,000 ppm or less, and more preferably 500 ppm or less.

Further, the amount of the cationic impurities contained in the hole transport layer is preferably 500 ppm or less, and more preferably 250 ppm or less.

Furthermore, the amount of the nonionic impurities contained in the hole transport layer is preferably 1,000 ppm or less, and more preferably 100 ppm or less.

Such a hole transport layer in which the amounts of anionic impurities, cationic impurities and nonionic impurities contained therein are respectively controlled to within such small ranges is reliably formed by using a hole transport material described below, for example.

Namely, as for the hole transport material, it is preferred that when the hole transport material is dissolved or dispersed in a liquid so that the concentration thereof becomes 2.0 wt % (hereinafter, referred to as “2.0 wt % dispersion liquid”), the amounts of the anionic impurities, cationic impurities and nonionic impurities contained in the liquid are 30 ppm or less, 30 ppm or less, and 40 ppm or less, respectively, and that the total amount of these three impurities is 90 ppm or less.

By forming the hole transport layer using such a hole transport material as described above, it is possible to reliably set the amounts of anionic impurities, cationic impurities, nonionic impurities contained in the hole transport layer to a value within the above mentioned range.

In particular, the amount of anionic impurities contained in the dispersion liquid is preferably 20 ppm or less, and more preferably 10 ppm or less.

Further, the amount of cationic impurities contained in the dispersion liquid is preferably 10 ppm or less, and more preferably 5 ppm or less.

Furthermore, the amount of nonionic impurities contained in the dispersion liquid is preferably 20 ppm or less, and more preferably 2 ppm or less.

Moreover, the total amount of these anionic impurities, cationic impurities and nonionic impurities contained in the dispersion liquid is preferably 50 ppm or less, and more preferably 20 ppm or less.

As for anionic impurities to be eliminated, various anionic impurities can be mentioned. In particular, it is preferred that at least one of SO₄²⁻ (sulfate ion), HCO₂⁻ (formate ion), C₂O₄²⁻ (oxalate ion), and CH₃CO₂⁻ (acetate ion) is eliminated. All of these ions have extremely high reactivity with the hole transport material, so that they are particularly apt to deteriorate the hole transport material. Therefore, the elimination of such ions makes it possible to obtain a hole transport material which can more reliably suppress the decrease of light-emission luminance of the organic EL device 1.

Further, as for cationic impurities to be eliminated, various cationic impurities can also be mentioned. In particular, it is preferred that cationic impurities mainly containing metal ions are eliminated. Since metal ions also have extremely high reactivity with the hole transport material, they are also apt to deteriorate the hole transport material. Therefore, the elimination of cationic impurities mainly containing metal ions makes it possible to obtain a hole transport material which can more reliably suppress the decrease of light-emission luminance of the organic EL device 1.

As for such metal ions, ions of various metals can be mentioned. In particular, it is preferred that ions of at least one of metals belonging to group Ia, group IIa, group VIa, group VIIa, group VIII, and group IIb of the periodic table are eliminated. By eliminating these metal ions, the effect of suppressing the decrease of light-emission luminance of the organic EL device 1 is especially and conspicuously exhibited.

Although various causes can be mentioned on why nonionic impurities are mixed into the hole transport layer, one of the main causes seems to be that substances (especially, solvent) added to synthesize the hole transport material, which is a major component of the hole transport layer, and substances produced in the course of the synthesis (such as unexpectedly synthesized substances or resolvents, for example) are not sufficiently eliminated.

Examples of such substances (that is, nonionic impurities) include one or more kinds of multiple alcohol such as diethylene glycol (DEG), ethylene glycol and glycerin, and aromatic heterocyclic compound such as N-methyl-pyrrolidone. It is highly likely that these substances cause a structural change of the hole transport material with the elapse of time. Therefore, by eliminating these substances, it is possible to reliably prevent the deterioration of the hole transport layer from occurring with the elapse of time.

As for the nonionic impurities to be eliminated, impurities formed and/or mixed when the hole transport material is synthesized can be -mentioned. Further, substances produced due to the decomposition of the hole transport material when the hole transport material is preserved can be also mentioned.

For example, as for nonionic impurities contained in the hole transport layer, which is formed of the hole transport material mainly constituted of a poly(thiophene/styrenesulfonate)-based compound, ethylene glycol can be mentioned.

By forming the hole transport layer using such a hole transport material as described above, it is possible to reliably control the amounts of anionic impurities, cationic impurities, nonionic impurities contained in the hole transport layer to a value within the above mentioned range.

In this regard, it is to be noted that so long as the amount of anionic impurities, cationic impurities and nonionic impurities contained in the hole transport layer finally obtained is controlled to a value within the above mentioned range, it is not necessary for the hole transport layer to be formed using such a hole transport material.

Such a hole transport material is refined in the following manner. First, a solution or a dispersion liquid in which the hole transport material is dissolved or dispersed is prepared. Then, anionic impurities, cationic impurities and nonionic impurities having a molecular weight of 5,000 or less are eliminated from the solution or dispersion liquid using a first elimination means for separating or eliminating the anionic impurities, a second elimination means for separating or eliminating the cationic impurities, and a third elimination means for separating or eliminating the nonionic impurities at substantially the same time or successively. Then, the solvent or dispersion medium is removed from the liquid, thereby refining the hole transport material.

Here, examples of the first and second elimination means include a filter, a column filler (adsorbent), a permeable membrane (dialyzer), and a medium with a density gradient.

Specifically, examples of the elimination method using the first and second elimination means include: a filtration method; various chromatography methods such as an adsorption chromatography method, an ion exchange chromatography method, a partition (normal phase or reverse phase) chromatography method, a molecular sieve chromatography method (gel filtration), a countercurrent distribution chromatography method, and a droplet countercurrent distribution chromatography method; a centrifugal separation method such as density gradient centrifugation; an ultrafiltration method; and a dialysis method.

Among these elimination methods using the first and second elimination means, a filtration method is preferably employed for each elimination means. According to the filtration method, it is possible to relatively easily eliminate anionic impurities and cationic impurities from the hole transport material in a short period of time. Further, only by appropriately selecting the kind of filter to be used, target anionic and cationic impurities can be efficiently and reliably eliminated.

Further, examples of the third elimination means include a ultrafiltration membrane, a filter, a column filler (adsorbent), and a permeable membrane (dialyzer).

Among these elimination means, the ultrafiltration membrane is preferably employed as the third elimination means. By using the ultrafiltration membrane as an elimination means, it is possible to relatively easily eliminate nonionic impurities from a solvent or a dispersion medium in a short period of time. Further, since the ultrafiltration membrane has an excellent separation property for various substances according to molecular weights thereof, only by appropriately selecting the kind of ultrafiltration membrane to be used, target nonionic impurities can be efficiently and reliably eliminated.

Namely, by employing the ultrafiltration membrane as a third elimination means, the elimination of nonionic impurities can be carried out with particularly high accuracy.

In this regard, it is to be noted that the first elimination means is not only for separating or eliminating anionic impurities, but may also have ability for separating or eliminating cationic and/or nonionic impurities.

Further, the second elimination means is also not only for separating or eliminating cationic impurities, but may also have ability for separating or eliminating nonionic impurities and/or anionic impurities.

Furthermore, the third elimination mean is also not only for separating or eliminating nonionic impurities, but may also have ability for separating or eliminating anionic and/or cationic impurities.

Hereinafter, a detailed description will be made with regard to the representative case in which as for the method for eliminating each anionic and cationic impurities the filtration method is employed, and as for the method for eliminating nonionic impurities the ultrafiltration is employed.

First, in the filtration method, a solution for refinement obtained by dissolving a hole transport material in a solvent or a dispersion liquid for refinement obtained by dispersing a hole transport material in a dispersion medium (hereinafter, these are referred to as “solution for refinement”) is passed through a filter to separate and eliminate each of anionic impurities and cationic impurities from the solution for refinement.

When the solution for refinement is prepared, the same solvents (or dispersion medium) that have been mentioned with reference to the method for manufacturing the organic EL device 1 (process of forming the hole transport layer 41) can be used.

As for a filter to be used in the filtration method, various filters can be used. In the case of cationic impurities, a filter formed using a cation-exchange resin as its main component is suitably used, and in the case of anionic impurities, a filter formed using an anion-exchange resin as its main component is suitably used. By using such a filter, it is possible to efficiently eliminate target ionic impurities from the hole transport material.

Examples of such a cation-exchange resin include strongly acidic cation-exchange resins, weakly acidic cation-exchange resins, and chelating resins capable of selectively eliminating heavy metals. For example, those obtained by introducing various functional groups such as —SO₃M, —COOM, and —N═(CH₂COO)₂M (M is preferably to be hydrogen) into main chains of various polymers such as styrene-based polymers, methacrylic polymers and acrylic polymers can be used. In this regard, it is to be noted that the functional group is appropriately selected depending on the kind of cation-exchange resin, and the like.

On the other hand, examples of such an anion-exchange resin include strongest basic anion-exchange resins, strongly basic anion-exchange resins, medium basic anion-exchange resins, and weakly basic anion-exchange resins. For example, those obtained by introducing various functional groups such as quaternary ammonium base and tertiary amine into main chains of various polymers such as styrene-based polymers and acrylic polymers can be used. In this regard, it is to be noted that the functional group is appropriately selected depending on the kind of anion-exchange resin, and the like.

The rate at the time when the solution for refinement is passed through a filter (hereinafter, referred to as “liquid passage rate”) is not limited to any specific value, but is preferably in the range of about 1 to 1, 000 mL/min, more preferably in the range of about 50 to 100 mL/min. By setting the liquid passage rate of the solution for refinement to a value within the above range, it is possible to more efficiently carry out the elimination of anionic impurities and cationic impurities.

Further, the temperature of the solution for refinement (hereinafter, referred to as “solution temperature”) is also not limited to any specific value, but it is preferred that the temperature is as high as possible within the range that does not interfere with the operation for eliminating ionic impurities. Namely, the solution temperature is preferably in the range of about 0 to 80° C., more preferably in the range of about 10 to 25° C. By setting the solution temperature to a value within the above range, it is possible to more efficiently carry out the elimination of anionic impurities and cationic impurities.

In this case, the solution for refinement may be passed through a filter not only once but also two or more times, or it may also be passed through different kinds of two or more filters. Further, these filtering operations may be carried out in combination. By doing so, it is possible to more efficiently eliminate anionic impurities and cationic impurities.

Next, in the ultrafiltration method, the solution for refinement, from which anionic impurities and cationic impurities have been eliminated by the filtration method, is passed through an ultrafiltration membrane to separate and eliminate nonionic impurities from the solution for refinement, and then the solvent (or the dispersion medium) is removed.

As for an ultrafiltration membrane used in the utrafiltration method, an aperture diameter thereof may be selected depending on a molecular weight of nonionic impurities to be eliminated.

The rate at the time when the solution for refinement is passed through an ultrafiltration membrane (that is, “liquid passage rate”) is not limited to any specific value, but is preferably in the range of about 1 to 100 mL/min, more preferably in the range of about 1 to 20 mL/min. By setting the liquid passage rate of the solution for refinement to a value within the above range, it is possible to more efficiently carry out the elimination of nonionic impurities.

Further, the temperature of the solution for refinement (that is, “solution temperature”) is also not limited to any specific value, but it is preferred that the temperature is as high as possible within the range that does not interfere with the operation for eliminating nonionic impurities. Namely, the solution temperature is preferably in the range of about 0 to 80° C., more preferably in the range of about 10 to 25° C. By setting the solution temperature to a value within the above range, it is possible to more efficiently carry out the elimination of nonionic impurities.

In this case, the solution for refinement may be passed through a ultrafiltration membrane not only once but also two or more times, or it may also be passed through different kinds of ultrafiltration membranes. Further, these filtering operations may be carried out in combination. By doing so, it is possible to more efficiently eliminate nonionic impurities.

Through the above-mentioned processes, the amount of each impurities in the hole transport material is controlled (adjusted) to a value within the above-mentioned range.

Further, the order of employing the filtration method and the ultrafiltration method may be inverted, or these two methods may also be employed at substantially the same time.

Furthermore, the solution for refinement after being refined may be directly employed to manufacture the organic EL device without removing the solvent (or the dispersion medium), or may also be employed to manufacture the organic EL device after being concentrated or diluted.

In the foregoing, the hole transport material, the layer formed of the hole transport material, the organic electroluminescent device, and the method of manufacturing the hole transport material according to the present invention have been described, but the present invention is not limited to thereto.

### ACTUAL EXAMPLES

Next, actual examples of the first and second embodiments of the present invention will be described.

### Examples of First Embodiment

First, a description will be made with regard to examples of the first embodiment directed to an amount of nonionic impurities having a molecular weight of 5,000 or less contained in a hole transport material and a hole transport layer.

In this regard, it is to be noted that no nonionic impurities were detected in the ultrapure water used in each of Examples and Comparative Examples described below.

Further, five organic EL devices were manufactured in each of Examples and Comparative Examples described below.

1. Method for Manufacturing Organic EL Device

### Example 1A

<Refinement of Hole Transport Material>

First, a 2.0 wt % aqueous solution of poly(3,4-ethylenedioxythiophene/styrenesulfonic acid) solution (which is a hole transport material and is manufactured by Bayer Corp. under the product name of “Baytron P”) was prepared as a solution for refinement.

In the poly(3,4-ethylenedioxythiophene/styrenesulfonic acid) used, a weight ratio of 3,4-ethylenedioxythiophene to styrenesulfonic acid was 1:2.

Next, the solution for refinement was diluted with ultrapure water by 10 times to prepare a solution.

Next, the thus prepared solution for refinement was passed through an ultrafiltration cell (which was an agitation-type cell, model 8200 manufactured by Millipore Ltd., and ultrafiltration membrane thereof had a cut-off molecular weight of 3,000) and then it was concentrated until the amount thereof became the same as the amount of the solution for refinement before being diluted, to eliminate nonionic impurities having a cut-off molecular weight of 3,000 or less.

In this regard, it is to be noted that the temperature of the solution for refinement (solution temperature) was set to 20° C. and the rate at the time when the solution for refinement was passed through the ultrafiltration cell (liquid passage rate) was set to 10 mL/min.

Next, a dispersion medium in the solution for refinement from which nonionic impurities have been eliminated was volatilized to remove it, to thereby obtain a refined hole transport material.

The solution for refinement from which nonionic impurities were eliminated in the manner described above was used as a hole transport layer material (a material for forming a hole transport layer) for forming a hole transport layer.

<Manufacture of Organic EL Device>

First, a transparent glass substrate having an average thickness of 0.5 mm was prepared. Next, an ITO electrode (anode) having an average thickness of 100 nm was formed on the substrate by a vacuum deposition method.

Next, a dispersion liquid obtained by dispersing the hole transport material in ultrapure water so that its concentration became 2.0 wt % was applied on the ITO electrode by a spin coating method and was then dried, to form a hole transport layer having an average thickness of 50 nm.

Next, a xylene solution containing 1.7 wt % of poly(9,9-dioctyl-2,7-divinylenefluorenyl-alt-co(anthracene-9,10 -diyl) (having a weight average molecular weight of 200,000) was applied on the hole transport layer by a spin coating method and was then dried, to form a light emitting layer having an average thickness of 50 nm.

Next, an electron transport layer having an average thickness of 20 nm was formed on the light emitting layer by vacuum deposition of 3,4,5-triphenyl-1,2,4-triazole.

Next, an AlLi electrode (cathode) having an average thickness of 300 nm was formed on the electron transport layer by a vacuum deposition method.

Next, a protection cover made of polycarbonate was coated so as to cover the thus formed layers, and was fixed and sealed with an ultraviolet rays-curable resin, to complete the organic EL device.

### Example 2A

Refinement of a hole transport material was carried out in the same manner as in Example 1A except that the dilution ratio of the solution for refinement with ultrapure water was 20 times, and then the organic EL devices were manufactured.

### Example 3A

Refinement of a hole transport material was carried out in the same manner as in Example 1A except that the dilution ratio of the solution for refinement with ultrapure water was 1.5 times, and then the organic EL devices were manufactured.

### Example 4A

First, a 2.0 wt % aqueous solution of poly(3,4-ethylenedioxythiophene/styrenesulfonic acid) solution (which is a hole transport material and is manufactured by Bayer Corp. under the product name of “Baytron P”) was prepared as a solution for refinement.

In the poly(3,4-ethylenedioxythiophene/styrenesulfonic acid) used, a weight ratio of 3,4-ethylenedioxythiophene to styrenesulfonic acid was 1:2.

Next, the thus prepared solution for refinement was passed through an ultrafiltration cell (which was an agitation-type cell, model 8200 manufactured by Millipore Ltd., and ultrafiltration membrane thereof had a cut-off molecular weight of 3,000), and then the solution for refinement was concentrated until the amount thereof was reduced by half, to eliminate nonionic impurities having a cut-off molecular weight of 3,000 or less.

In this regard, it is to be noted that the temperature of the solution for refinement (solution temperature) was set to 20° C. and the rate at the time when the solution for refinement was passed through the ultrafiltration cell (liquid passage rate) was set to 10 mL/min.

Next, a dispersion medium in the solution for refinement from which nonionic impurities have been eliminated was volatilized to remove it, to thereby obtain a refined hole transport material.

Next, using the thus obtained refined hole transport material as a material for forming a hole transport layer, the organic EL devices were manufactured in the same manner as in Example 1A.

### Example 5A

Refinement of a hole transport material was carried out in the same manner as in Example 1A except that an ultrafiltration cell (which was an agitation-type cell, model 8200 manufactured by Millipore Ltd., and ultrafiltration membrane thereof had a cut-off molecular weight of 5,000) was used to eliminate nonionic impurities having a cut-off molecular weight of 5,000 or less, and then the organic EL devices were manufactured.

### Example 6A

Refinement of a hole transport material was carried out in the same manner as in Example 2A except that an ultrafiltration cell (which was an agitation-type cell, model 8200 manufactured by Millipore Ltd., and ultrafiltration membrane thereof had a cut-off molecular weight of 5, 000) was used to eliminate nonionic impurities having a cut-off molecular weight of 5,000 or less, and then the organic EL devices were manufactured.

### Example 7A

Refinement of a hole transport material was carried out in the same manner as in Example 3A except that an ultrafiltration cell (which was an agitation-type cell, model 8200 manufactured by Millipore Ltd., and ultrafiltration membrane thereof had a cut-off molecular weight of 5,000) was used to eliminate nonionic impurities having a cut-off molecular weight of 5,000 or less, and then the organic EL devices were manufactured.

### Example 8A

Refinement of a hole transport material was carried out in the same manner as in Example 4A except that an ultrafiltration cell (which was an agitation-type cell, model 8200 manufactured by Millipore Ltd., and ultrafiltration membrane thereof had a cut-off molecular weight of 5,000) was used to eliminate nonionic impurities having a cut-off molecular weight of 5,000 or less, and then the organic EL devices were manufactured.

### Comparative Example 1A

Refinement of a hole transport material was carried out in the same manner as in Example 1A except that the dilution ratio of the solution for refinement with ultrapure water was 1.3 times, and then the organic EL devices were manufactured.

### Comparative Example 2A

Refinement of a hole transport material was carried out in the same manner as in Example 1A except that the dilution ratio of the solution for refinement with ultrapure water was 1.1 times, and then the organic EL devices were manufactured.

### Comparative Example 3A

A hole transport material same as that used in Example 1A was prepared and then refinement of the hole transport material was carried out in the same manner as in Example 1A except that the elimination of the nonionic impurities was omitted.

2. Evaluation

2-1. Measurement of Amount of Nonionic Impurities

The amount of the nonionic impurities contained in the refined hole transport material obtained in each of Examples 1A to 6A and Comparative Examples 1A to 3A was measured. The measurement was carried out using a ¹H-NMR method. In more details, a dispersion liquid in which the hole transport material was dispersed so that its concentration become 2 wt % was analyzed by the ¹H-NMR method.

According to the result of the measurement by the ¹H-NMR method, a peak derived from PEDT/PSS and a peak derived from ethylene glycol, which was one of nonionic impurities having a molecular weight of 5, 000 or less, were recognized from the spectrum of the ¹H-NMR.

Based on these peaks recognized, an area of the peak derived from the styrene unit and an area of the peak derived from the ethylene glycol were measured. Then, based on the ratio of the areas of the peaks, the number of ethylene glycol with respect to 1, 000 styrene units (hereinafter, referred to as “the number of ethylene glycol”) was obtained.

The amount of the nonionic impurities (ppm) contained in the refined hole transport material was calculated from the obtained number of ethylene glycol, the concentration of the hole transport material (PEDT/PSS) in the solution and the weight ratio of the PEDT/PSS.

Further, the amount of the nonionic impurities in the hole transport layer of the organic EL device was measured in the same manner as the ¹H-NMR method.

2-2. Evaluation of Decrease of Light-Emission Luminance of Organic EL Device

Light-emission luminance of the organic EL device obtained in each of Examples 1A to 8A and Comparative Examples 1A to 3A was measured to determine the time elapsed before the initial value of light-emission luminance was decreased by half (a half-life).

In this regard, it is to be noted that the measurement of light-emission luminance was carried out by applying a voltage of 6V across the ITO electrode and the AlLi electrode.

The results of the evaluations 1 and 2 are shown in following Tables 1A-1 and 1A-2.

TABLE 1A-1
<In 2.0 wt % dispersion liquid>

| | | | | Evaluation of |
|---|---|---|---|---|
| | | | | decrease of |
| | | | | light-emission |
| | | Amount of nonionic impurities | | luminance |
| | Styrene | | Elimination | Half-life |
| | units | Ethylene glycol | ratio (%) | [Relative value] |
| Ex. 1 | 1000 | 1.0 (6.45 ppm) | 90.2 | 1.75 |
| Ex. 2 | 1000 | 0.4 (2.58 ppm) | 96.1 | 1.90 |
| Ex. 3 | 1000 | 5.0 (32.3 ppm) | 50.9 | 1.20 |
| Ex. 4 | 1000 | 2.0 (12.9 ppm) | 80.4 | 1.60 |
| Ex. 5 | 1000 | 1.2 (7.74 ppm) | 88.2 | 1.70 |
| Ex. 6 | 1000 | 0.3 (1.94 ppm) | 97.1 | 1.95 |
| Ex. 7 | 1000 | 5.2 (33.6 ppm) | 49.0 | 1.19 |
| Ex. 8 | 1000 | 2.5 (16.1 ppm) | 75.5 | 1.54 |
| Com. | 1000 | 6.7 (43.3 ppm) | 34.3 | 1.03 |
| Ex. 1 | | | | |
| Com. | 1000 | 9.1 (58.5 ppm) | 10.8 | 1.02 |
| Ex. 2 | | | | |
| Com. | 1000 | 10.2 (65.8 ppm) | 0.0 | 1.00 |
| Ex. 3 | | | | |

TABLE 1A-2
<In hole transport layer>

| | | | | Evaluation of |
|---|---|---|---|---|
| | | | | decrease of |
| | | | | light-emission |
| | | Amount of nonionic impurities | | luminance |
| | Styrene | | Elimination | Half-life |
| | units | Ethylene glycol | ratio (%) | [Relative value] |
| Ex. 1A | 1000 | 1.0 (322 ppm) | 90.2 | 1.75 |
| Ex. 2A | 1000 | 0.4 (129 ppm) | 96.1 | 1.90 |
| Ex. 3A | 1000 | 5.0 (1615 ppm) | 50.9 | 1.20 |
| Ex. 4A | 1000 | 2.0 (645 ppm) | 80.4 | 1.60 |
| Ex. 5A | 1000 | 1.2 (387 ppm) | 88.2 | 1.70 |
| Ex. 6A | 1000 | 0.3 (97 ppm) | 97.1 | 1.95 |
| Ex. 7A | 1000 | 5.2 (1678 ppm) | 49.0 | 1.19 |
| Ex. 8A | 1000 | 2.5 (805 ppm) | 75.5 | 1.54 |
| Com. | 1000 | 6.7 (2165 ppm) | 34.3 | 1.03 |
| Ex. 1A | | | | |
| Com. | 1000 | 9.1 (2925 ppm) | 10.8 | 1.02 |
| Ex. 2A | | | | |
| Com. | 1000 | 10.2 (3291 ppm) | 0.0 | 1.00 |
| Ex. 3A | | | | |

In these Tables, Table 1A-1 shows the amounts of ethylene glycol in 2.0 wt % dispersion liquids and Table 1A-2 shows the amounts of ethylene glycol in the hole transport layers.

Further, each numeric value indicated in the Tables is an average value of the 5 organic EL devices.

Furthermore, the elimination ratio (%) shown in Tables is calculated based on the number of ethylene glycol in Comparative Example 3A in which the elimination of the nonionic impurities was omitted, wherein the case where all the ethylene glycol in Comparative Example 3A could be eliminated is represented with 100%.

Moreover, the evaluation result of decrease of light-emission luminance of each organic EL device was shown by the relative value of half-life of light-emission luminance of the organic EL device of each of Examples 1A to 8A and Comparative Examples 1A and 2A. In this regard, it is to be noted that each value was determined by defining the half-life of light-emission luminance of the organic EL device manufactured using the non-refined hole transport material of Comparative Example 3A as “1”.

As shown in Tables 1A-1 and 1A-2, in the organic EL device of each of the Examples, the amount of ethylene glycol (nonionic impurities) in a 2.0 wt % dispersion liquid was 6 (40 ppm) or less with respect to 1,000 styrene units, and the amount of ethylene glycol in the hole transport layer was 6 (2000 ppm) or less with respect to 1,000 styrene units. This means that in each of Examples, ethylene glycol was eliminated with a higher elimination ratio.

In contrast, in each of Comparative Examples, the amount of ethylene glycol (nonionic impurities) in a 2.0 wt % dispersion liquid was larger than 6 (40 ppm) with respect to 1000 styrene units, and the amount of ethylene glycol in the hole transport material was larger than 6 (2000 ppm) with respect to 1,000 styrene units.

In this regard, it is to be noted that in each of Examples, the volume resistivity of the hole transport material was lager than that of each of Comparative Examples, and it was 10⁴ Ω·cm or larger.

Further, the organic EL device of each of Examples had a longer half-life of light-emission luminance as compared with the organic EL device of each of Comparative Examples, that is, the decrease of light-emission luminance was suppressed. Furthermore, each of Tables shows a tendency that the half-life of light-emission luminance of the organic EL device was more prolonged according to the decrease of the amount of ethylene glycol.

As described above, it has been found that an organic EL device using the hole transport material of the present invention, in which the amount of nonionic impurities is controlled to within a predetermined value, is excellent one. That is, in such an organic EL device, the decrease of light-emission luminance is suppressed and excellent light emitting properties are maintained for a long period of time.

### Examples of Second Embodiment

Hereinbelow, a description will be made with regard to examples of the second embodiment directed to amounts of anionic impurities, cationic impurities and nonionic impurities having a molecular weight of 5,000 or less contained in hole transport materials.

In this regard, it is to be noted that no anionic impurities, cationic impurities, and nonionic impurities were detected in the ultrapure water used below.

Further, five organic EL devices were manufactured in each of Examples and Comparative Examples described below.

2. Method for Manufacturing Organic EL Device

### Example 1B

<Refinement of Hole Transport Material>

First, a 2.0 wt % aqueous solution of poly(3,4-ethylenedioxythiophene/styrenesulfonic acid) (which is a hole transport material and is manufactured by Bayer Corp. under the product name of “Baytron P”) was prepared as a solution for refinement.

In the poly(3,4-ethylenedioxythiophene/styrenesulfonic acid) used, a weight ratio of 3,4-ethylenedioxythiophene to styrenesulfonic acid was 1:2.

Next, the solution for refinement was diluted with ultrapure water by 20 times.

Next, the thus prepared solution for refinement was passed through a column provided with six filters, which were respectively made of a styrene-based quaternary ammonium salt-type strongest basic anion-exchange resin, to eliminate anionic impurities.

In this regard, it is to be noted that the temperature of the solution for refinement (solution temperature) was set to 20° C. and the rate at the time when the solution for refinement was passed through the column (liquid passage rate) was set to 50 mL/min.

Next, the solution for refinement was passed through a column provided with six filters, which were respectively made of a styrene-based sulfonic acid-type strongly acidic cation-exchange resin, to eliminate cationic impurities.

In this regard, it is to be noted that the temperature of the solution for refinement (solution temperature) was set to 20° C. and the rate at the time when the solution for refinement was passed through the column (liquid passage rate) was set to 50 mL/min.

Next, the solution for refinement was passed through an ultrafiltration cell (which was an agitation-type cell, model 8200 manufactured by Millipore Ltd., and ultrafiltration membrane thereof had a cut-off molecular weight of 5,000) and then it was concentrated until the amount thereof becomes the same as the solution for refinement before being diluted, to eliminate nonionic impurities having a cut-off molecular weight of 5,000 or less.

In this regard, it is to be noted that the temperature of the solution for refinement (solution temperature) was set to 20° C. and the rate at the time when the solution for refinement was passed through the column (liquid passage rate) was set to 10 mL/min.

Next, a dispersion medium in the solution for refinement from which each impurities have been eliminated was volatilized to remove it, to thereby obtain a refined hole transport material.

<Manufacture of Organic EL Device>

First, a transparent glass substrate having an average thickness of 0.5 mm was prepared. Next, an ITO electrode (anode) having an average thickness of 100 nm was formed on the substrate by a vacuum deposition method.

Next, a dispersion liquid obtained by dispersing the hole transport material in ultrapure water so that its concentration became 2.0 wt % was applied on the ITO electrode by a spin coating method and was then dried, to form a hole transport layer having an average thickness of 50 nm.

Next, a xylene solution containing 1.7 wt % of poly(9,9-dioctyl-2,7-divinylenefluorenyl-alt-co(anthracene-9,10-diyl) (having a weight average molecular weight of 200,000) was applied on the hole transport layer by a spin coating method and was then dried, to form a light emitting layer having an average thickness of 50 nm.

Next, an electron transport layer having an average thickness of 20 nm was formed on the light emitting layer by vacuum deposition of 3,4,5-triphenyl-1,2,4-triazole.

Next, an AlLi electrode (cathode) having an average thickness of 300 nm was formed on the electron transport layer by a vacuum deposition method.

Next, a protection cover made of polycarbonate was coated so as to cover the thus formed layers, and was fixed and sealed with an ultraviolet rays-curable resin, to complete the organic EL device.

### Example 2B

<Refinement of Hole Transport Material>

A 2.0 wt % aqueous soloution of poly(3,4-ethylenedioxythiophene/styrenesulfonic acid) solution (which is a hole-transport material and is manufactured by Bayer Corp. under the product name of “Baytron P”) which is the same as that used in the Example 1 was prepared as a solution for refinement.

Next, the solution for refinement was diluted with ultrapure water by 10 times.

Next, the thus prepared solution for refinement was passed through a column provided with four filters, which were made of a styrene-based quaternary ammonium salt-type strongest basic anion-exchange resin, to eliminate anionic impurities.

In this regard, it is to be noted that the temperature of the solution for refinement (solution temperature) was set to 20° C. and the rate at the time when the solution for refinement was passed through the column (liquid passage rate) was set to 50 mL/min.

Next, the solution for refinement was passed through a column provided with four filters, which were respectively made of a styrene-based sulfonic acid-type strongly acidic cation-exchange resin, to eliminate cationic impurities.

In this regard, it is to be noted that the temperature of the solution for refinement (solution temperature) was set to 20° C. and the rate at the time when the solution for refinement was passed through the column (liquid passage rate) was set to 50 mL/min.

Next, the solution was passed through an ultrafiltration cell (which was an agitation-type cell, model 8200 manufactured by Millipore Ltd., and ultrafiltration membrane thereof had a cut-off molecular weight of 5,000) and then concentrated until the amount thereof becomes the same as the solution for refinement before being diluted, to eliminate nonionic impurities having a cut-off molecular weight of 5,000 or less.

In this regard, it is to be noted that the temperature of the solution for refinement (solution temperature) was set to 20° C. and the rate at the time when the solution for refinement was passed through the column (liquid passage rate) was set to 10 mL/min.

Next, a dispersion medium in the solution for refinement from which each impurities has been eliminated was volatilized to remove it, to thereby obtain a refined hole transport material.

<Manufacture of Organic EL Device>

Organic EL devices were manufactured in the same manner as in Example 1B using the refined hole transport material obtained in the above-mentioned manner.

### Example 3B

<Refinement of Hole Transport Material>

A 2.0 wt % aqueous solution of poly(3,4-ethylenedioxythiophene/styrenesulfonic acid) solution (which is a hole transport material and is manufactured by Bayer Corp. under the product name of “Baytron P”) which was the same as that used in the Example 1 was prepared as a solution for refinement.

Next, the solution for refinement was diluted with ultrapure water by 1.5 times.

Next, the thus prepared solution for refinement was passed through a column provided with two filters, which were respectively made of a styrene-based quaternary ammonium salt-type strongest basic anion-exchange resin, to eliminate anionic impurities.

In this regard, it is to be noted that the temperature of the solution for refinement (solution temperature) was set to 20° C. and the rate at the time when the solution for refinement was passed through the column (liquid passage rate) was set to 50 mL/min.

Next, the solution for refinement was passed through a column provided with two filters, which were respectively made of a styrene-based sulfonic acid-type strongly acidic cation-exchange resin, to eliminate cationic impurities.

In this regard, it is to be noted that the temperature of the solution for refinement (solution temperature) was set to 20° C. and the rate at the time when the solution for refinement was passed through the column (liquid passage rate) was set to 50 mL/min.

Next, the solution for refinement was passed through an ultrafiltration cell (which was an agitation-type cell, model 8200 manufactured by Millipore Ltd., and ultrafiltration membrane thereof had a cut-off molecular weight of 5,000) and then it was concentrated until the amount thereof becomes the same as the solution for refinement before being diluted, to eliminate nonionic impurities having a cut-off molecular weight of 5,000 or less.

In this regard, it is to be noted that the temperature of the solution for refinement (solution temperature) was set to 20° C. and the rate at the time when the solution for refinement was passed through the column (liquid passage rate) was set to 10 mL/min.

Next, a dispersion medium in the solution for refinement from which each impurities has been eliminated was volatilized to remove it, to thereby obtain a refined hole transport material.

<Manufacture of Organic EL Device>

Organic EL devices were manufactured in the same manner as in Example 1B using the refined hole transport material obtained in the above-mentioned manner.

### Example 4B

Refinement of a hole transport material was carried out in the same manner as in Example 3B except that the two filters to eliminate anionic impurities were replaced with six filters, and then the organic EL devices were manufactured.

### Example 5B) Refinement

of a hole transport material was carried out in the same manner as in Example 3B except that the two filters to eliminate cationic impurities were replaced with six filters, and then the organic EL devices were manufactured.

### Example 6B

Refinement of a hole transport material was carried out in the same manner as in Example 3B except that the dilution ratio of the solution for refinement with ultrapure water was 20 times, and then the organic EL devices were manufactured.

### Comparative Example 1B

Refinement of a hole transport material was carried out in the same manner as in Example 3B except that the dilution of the solution for refinement with ultrapure water and the elimination of nonionic impurities having a molecular weight of 5,000 or less were omitted, and then the organic EL devices were manufactured.

### Comparative Example 2B

Refinement of a hole transport material was carried out in the same manner as in Example 3B except that the eliminations of cationic impurities and nonionic impurities having a molecular weight of 5,000 or less were omitted, and then the organic EL devices were manufactured.

### Comparative Example 3B

Refinement of a hole transport material was carried out in the same manner as in Example 3B except that the eliminations of anionic impurities and nonionic impurities having a molecular weight of 5,000 or less were omitted, and then the organic EL devices were manufactured.

### Comparative Example 4B

Refinement of a hole transport material was carried out in the same manner as in Example 3B except that the eliminations of anionic impurities, cationic impurities, and nonionic impurities having a molecular weight of 5,000 or less were omitted, and then the organic EL devices were manufactured.

<Evaluation>

1. Measurement of Amount of Ionic Impurities

1-1. Measurement of Amount of Anionic Impurities

The amount of the anionic impurities contained in the refined hole transport material obtained in each of Examples 1B to 6B and Comparative Examples 1B to 3B, and the amount of the anionic impurities contained in the hole transport material of Comparative Example 4B were measured using an Ion Chromatography method (IC method), respectively.

Specifically, each hole transport material was dispersed in ultrapure water so that the concentration thereof became 2.0 wt %, to obtain a dispersion liquid. This dispersion liquid was analyzed by an IC method.

Further, the amount of the anionic impurities contained in the hole transport layer of each organic EL device was determined by calculating the measurement value obtained here.

1-2. Measurement of Amount of Cationic Impurities The amount of the cationic impurities contained in the refined hole transport material obtained in each of Examples 1B to 6B and Comparative Examples 1B to 3B, and the amount of the cationic impurities contained in the hole transport material of Comparative Example 4B were measured using an Inductively coupled plasma mass spectroscopy method (ICP-MS method), respectively.

Specifically, 0. 5 g of a solution obtained by dissolving the hole transport material in ultrapure water so that the concentration thereof became 2.0 wt % was weighed in a quartz crucible, and an ashing treatment was successively carried out with a hot plate and an electric furnace. Next, the ashed matter was subjected to thermolysis using nitric acid, and was then made up to a constant volume with dilute nitric acid. The obtained solution with a constant volume was analyzed by an ICP-MS method.

The analytical results were evaluated according to the following seven criteria depending on the amount of the cationic impurities.

Further, the amount of the cationic impurities contained in the hole transport layer of each organic EL device was determined by calculating the measurement value obtained here.

<Amount of the Cationic Impurities Contained in 2.0 wt % Solution>

−: 0.1 ppm or less

+: more than 0.1 ppm but 1 ppm or less

2+: more than 1 ppm but 5 ppm or less

3+: more than 5 ppm but 10 ppm or less

4+: more than 10 ppm but 30 ppm or less

5+: more than 30 ppm but 500 ppm or less

6+: more than 500 ppm

<Amount of the Cationic Impurities Contained in Hole Transport Layer>

−: 5 ppm or less

+: more than 5 ppm but 50 ppm or less

2+: more than 50 ppm but 250 ppm or less

3+: more than 250 ppm but 500 ppm or less

4+: more than 500 ppm but 1,500 ppm or less

5+: more than 1,500 ppm but 25,000 ppm or less

6+: more than 25,000 ppm

1-3. Measurement of Amount of Nonionic Impurities

The amount of the nonionic impurities contained in the refined hole transport material obtained in each of Examples 1B to 6B and Comparative Examples 1B to 3B, and the amount of the nonionic impurities contained in the hole transport material of Comparative Example 4B were measured using a ¹H-NMR method, respectively. In more details, a dispersion liquid in which the hole transport material was dispersed so that its concentration become 2 wt % was analyzed by the ¹H-NMR method.

According to the result of the measurement by the ¹H-NMR method, a peak derived from PEDT/PSS and a peak derived from ethylene glycol which is one of nonionic impurities having a molecular weight of 5,000 or less were recognized from the spectrum of the ¹H-NMR.

Based on these peaks recognized, a molar ratio of styrene unit to ethylene glycol was calculated from a ratio of an area of the peak derived from the styrene unit to an area of the peak derived from the ethylene glycol. The amount of the nonionic impurities (ppm) contained in the refined hole transport material was calculated from the obtained molar ratio of styrene unit to ethylene glycol, the concentration of the hole transport material (PEDT/PSS) in the solution and the weight ratio of the PEDT/PSS.

Further, the amount of the nonionic impurities in the hole transport material of each organic EL device was measured in the same manner as the ¹H-NMR method.

2. Evaluation of Decrease of Light-Emission Luminance of Organic EL Device

Light-emission luminance of the organic EL device obtained in each of Examples 1B to 3B and Comparative Examples 1B to 3B was measured to determine the time elapsed before the initial value of light-emission luminance was decreased by half (a half-life).

In this regard, it is to be noted that the measurement of light-emission luminance was carried out by applying a voltage of 6V across the ITO electrode and the AlLi electrode.

The results of the evaluations 1B and 2B are shown in following Tables 2B-1 and 2B-2.

TABLE 2B-1
<In 2.0 wt % solution>

| | | | | | | | | | | | | | | | | | | | Evaluation |
|---|---|---|---|---|---|---|---|---|---|---|---|---|---|---|---|---|---|---|---|
| | | | | | | | | | | | | | | | | | | | of decrease |
| | | | | | | | | | | | | | | | | | | | of light- |
| | | | | | | | | | | | | | | | | | | | emission |
| | Amount of impurities | | | | | | | | | | | | | | | | | | luminance |
| | | | | | | | | | | | | | | | | | Nonionic | | Half-life |
| | Anionic Impurities [ppm] | | | | | Cationic impurities | | | | | | | | | | | impurities | Total | (Relative |
| | SO₄²⁻ | HCO₂⁻ | C₂O₄²⁻ | CH₃CO₂⁻ | Total | Na | Mg | K | Ca | Cr | Mn | Fe | Ni | Zn | Sr | Total | [ppm] | [ppm] | value) |
| Ex. 1B | 7.8 | 0.7 | 0.2 | 0.1 | 9.1 | − | − | − | + | − | − | − | − | − | − | 2+ | 1.95 | 20 or | 2.10 |
| | | | | | | | | | | | | | | | | | | less | |
| Ex. 2B | 12.1 | 1.6 | 0.6 | 0.5 | 18.4 | 2+ | + | + | 2+ | + | + | + | + | + | + | 3+ | 18.92 | 50 or | 2.05 |
| | | | | | | | | | | | | | | | | | | less | |
| Ex. 3B | 16.9 | 2.4 | 1.1 | 1.1 | 27.8 | 3+ | + | + | 3+ | + | + | + | + | + | + | 4+ | 31.70 | 90 or | 1.98 |
| | | | | | | | | | | | | | | | | | | less | |
| Ex. 4B | 8.0 | 0.6 | 0.3 | 0.1 | 9.3 | 3+ | + | + | 3+ | + | + | + | + | + | + | 4+ | 32.02 | 80 or | 1.88 |
| | | | | | | | | | | | | | | | | | | less | |
| Ex. 5B | 16.5 | 2.3 | 1.0 | 1.3 | 27.6 | − | − | − | + | − | − | − | − | − | − | 2+ | 31.84 | 70 or | 1.80 |
| | | | | | | | | | | | | | | | | | | less | |
| Ex. 6B | 16.7 | 2.2 | 1.3 | 1.2 | 27.5 | 3+ | + | + | 3+ | + | + | + | + | + | + | 4+ | 1.98 | 60 or | 1.90 |
| | | | | | | | | | | | | | | | | | | less | |
| Com. | 17.0 | 2.2 | 1.0 | 1.4 | 28.8 | 3+ | + | + | 3+ | + | + | + | + | + | + | 4+ | 61.10 | More | 1.50 |
| Ex. 1B | | | | | | | | | | | | | | | | | | than | |
| | | | | | | | | | | | | | | | | | | 90 | |
| Com. | 16.1 | 2.1 | 1.0 | 1.2 | 27.4 | 6+ | + | + | 3+ | 3+ | + | 3+ | + | + | + | 6+ | 63.72 | More | 1.35 |
| Ex. 2B | | | | | | | | | | | | | | | | | | than | |
| | | | | | | | | | | | | | | | | | | 90 | |
| Com. | 58.1 | 5.1 | 4.2 | 4.2 | 75.7 | 3+ | + | + | 3+ | + | + | + | + | + | + | 4+ | 62.82 | More | 1.32 |
| Ex. 3B | | | | | | | | | | | | | | | | | | than | |
| | | | | | | | | | | | | | | | | | | 90 | |
| Com. | 59.5 | 5.2 | 4.3 | 4.4 | 76.0 | 6+ | + | + | 3+ | 3+ | + | 3+ | + | + | + | 6+ | 65.28 | More | 1.00 |
| Ex. 4B | | | | | | | | | | | | | | | | | | than | |
| | | | | | | | | | | | | | | | | | | 90 | |

−: 0.1 ppm or less
+: more than 0.1 ppm but 1 ppm or less
2+: more than 1 ppm but 5 ppm or less
3+: more than 5 ppm but 10 ppm or less
4+: more than 10 ppm but 30 ppm or less
5+: more than 30 ppm but 500 ppm or less
6+: more than 500 ppm

TABLE 2B-2
<In hole transport layer>

| | | | | | | | | | | | | | | | | | | | Evaluation |
|---|---|---|---|---|---|---|---|---|---|---|---|---|---|---|---|---|---|---|---|
| | | | | | | | | | | | | | | | | | | | of decrease |
| | | | | | | | | | | | | | | | | | | | of light- |
| | | | | | | | | | | | | | | | | | | | emission |
| | Amount of impurities | | | | | | | | | | | | | | | | | | luminance |
| | | | | | | | | | | | | | | | | | Nonionic | | Half-life |
| | Anionic impurities [ppm] | | | | | Cationic impurities | | | | | | | | | | | impurities | Total | (Relative |
| | SO₄²⁻ | HCO₂⁻ | C₂O₄²⁻ | CH₃CO₂⁻ | Total | Na | Mg | K | Ca | Cr | Mn | Fe | Ni | Zn | Sr | Total | [ppm] | [ppm] | value) |
| Ex. 1B | 390 | 35 | 10 | 5 | 455 | − | − | − | + | − | − | − | − | − | − | 2+ | 97.5 | 1000 or | 2.10 |
| | | | | | | | | | | | | | | | | | | less | |
| Ex. 2B | 605 | 80 | 30 | 25 | 920 | 2+ | + | + | 2+ | + | + | + | + | + | + | 3+ | 946 | 2500 or | 2.05 |
| | | | | | | | | | | | | | | | | | | less | |
| Ex. 3B | 845 | 110 | 55 | 55 | 1390 | 3+ | + | + | 3+ | + | + | + | + | + | + | 4+ | 1585 | 4500 or | 1.98 |
| | | | | | | | | | | | | | | | | | | less | |
| Ex. 4B | 400 | 30 | 15 | 5 | 465 | 3+ | + | + | 3+ | + | + | + | + | + | + | 4+ | 1601 | 4000 or | 1.88 |
| | | | | | | | | | | | | | | | | | | less | |
| Ex. 5B | 825 | 115 | 50 | 65 | 1380 | − | − | − | + | − | − | − | − | − | − | 2+ | 1592 | 3500 or | 1.80 |
| | | | | | | | | | | | | | | | | | | less | |
| Ex. 6B | 835 | 110 | 65 | 60 | 1375 | 3+ | + | + | 3+ | + | + | + | + | + | + | 4+ | 99.0 | 3000 or | 1.90 |
| | | | | | | | | | | | | | | | | | | less | |
| Com. | 850 | 110 | 50 | 70 | 1440 | 3+ | + | + | 3+ | + | + | + | + | + | + | 4+ | 3055 | More | 1.50 |
| Ex. 1B | | | | | | | | | | | | | | | | | | than | |
| | | | | | | | | | | | | | | | | | | 4500 | |
| Com. | 805 | 105 | 50 | 60 | 1370 | 6+ | + | + | 3+ | 3+ | + | 3+ | + | + | + | 6+ | 3186 | More | 1.35 |
| Ex. 2B | | | | | | | | | | | | | | | | | | than | |
| | | | | | | | | | | | | | | | | | | 4500 | |
| Com. | 2905 | 255 | 210 | 210 | 3785 | 3+ | + | + | 3+ | + | + | + | + | + | + | 4+ | 3141 | More | 1.32 |
| Ex. 3B | | | | | | | | | | | | | | | | | | than | |
| | | | | | | | | | | | | | | | | | | 4500 | |
| Com | 2970 | 260 | 215 | 220 | 3795 | 6+ | + | + | 3+ | 3+ | + | 3+ | + | + | + | 6+ | 3264 | More | 1.00 |
| Ex. 4B | | | | | | | | | | | | | | | | | | than | |
| | | | | | | | | | | | | | | | | | | 4500 | |

−: 5 ppm or less
+: more than 5 ppm but 50 ppm or less
2+: more than 50 ppm but 250 ppm or less
3+: more than 250 ppm but 500 ppm or less
4+: more than 500 ppm but 1500 ppm or less
5+: more than 1500 ppm but 25000 ppm or less
6+: more than 25000 ppm

In Tables 2B-1 and 2B-2, the amounts of the impurities contained in 2.0 wt % solutions are shown in the Table 1-A and the amounts of the impurities contained in the hole transport layers are shown in the Table 1-B.

Further, each numeric value indicated in the Tables is an average value of the 5 organic EL devices.

Furthermore, it is to be noted that as for the anionic impurities, the amount of each of SO₄²⁻, HCO₂⁻, C₂O₄²⁻ and CH₃CO₂⁻, and the total amount of these are indicated. As for the cationic impurities, the amount of each of the cationic impurities and the total amount of those cationic impurities are indicated. As for the nonionic impurities, the amount of the ethylene glycol is indicated.

Moreover, the total value is the sum of the amounts of the anionic impurities, the cationic impurities and the nonionic impurities having a molecular weight of 5,000 or less.

Moreover, the evaluation result of decrease of light-emission luminance of each organic EL device was shown by the relative value of half-life of light-emission luminance of the organic EL device of each of Examples and Comparative Examples. In this regard, it is to be noted that each value was determined by defining the half-life of light-emission luminance of the organic EL device manufactured using the non-refined hole transport material of Comparative Example 4B as “1”.

As shown in Tables 2B-1 and 2B-2, in the organic EL device of each of Examples, the amount of each of the anionic impurities, the cationic impurities, the nonionic impurities having a molecular weight of 5,000 or less, and the total amount of these three impurities were 30 ppm or less, 30 ppm or less, 40 ppm or less, and 90 ppm or less, respectively in 2.0 aqueous solution, and further 1,500 ppm or less, 1,500 ppm or less, 2,000 ppm or less, and 4,500 ppm or less, respectively, in each of the hole transport layers.

Further, the organic EL device of each of Examples had a longer half-life of light-emission luminance as compared with the organic EL device of each of Comparative Examples, that is, the decrease of light-emission luminance was suppressed.

Furthermore, each of Tables shows a tendency that the half-life of light-emission luminance of the organic EL device is more prolonged by eliminating each of impurities in a balanced manner and further reducing the amount of each of the impurities and the total amount of these impurities.

In this connection, it is to be noted that the volume resistivity of the hole transport material of each of Examples was larger than that of the hole transport material of each of Comparative Examples, and was 10⁴ Ω·cm or larger.

As described above, it has been found that an organic EL device using the hole transport material of the present invention, in which the amount of each of the anionic impurities, cationic impurities and nonionic impurities having molecular weight of 5,000 or less is controlled to within a predetermined value, is excellent one. That is, in such an organic EL device, the decrease of light-emission luminance is suppressed and excellent light emitting properties are maintained for a long period of time.

Finally, it is to be understood that many changes and additions may be made to the embodiments described above without departing from the scope and spirit of the invention as defined in the following claims.

Further, it is also to be understood that the present disclosure relates to subject matters contained in Japanese Patent Applications No. 2003-362510 and No. 2003-362511 (both filed on Oct. 22, 2003) which are expressly incorporated herein by reference in their entireties.

1. A hole transport material to be used for a layer having the function of transporting holes in an organic EL device, the hole transport material being characterized in that when the hole transport material is dissolved or dispersed in a liquid so that its concentration becomes 2.0 wt %, the liquid contains nonionic impurities having a molecular weight of 5,000 or less, but an amount of the nonionic impurities contained therein is 40 ppm or less.

2. The hole transport material as claimed in claim 1, wherein the nonionic impurities mainly include those which are formed and/or mixed when synthesizing the hole transport material.

3. The hole transport material as claimed in claim 1, wherein the nonionic impurities include at least one of polyalcohol and heterocyclic aromatic compound.

4. The hole transport material as claimed in claim 1, wherein the hole transport material includes at least one selected from the group comprising thiophene/styrenesulfonate-based compounds, arylcycloalkane-based compounds, arylamine-based compounds, phenylenediamine-based compounds, carbazole-based compounds, stilbene-based compounds, oxazole-based compounds, triphenylmethane-based compounds, pyrazoline-based compounds, benzine-based compounds, triazole-based compounds, imidazole-based compounds, oxadiazole-based compounds, anthracene-based compounds, fluorenone-based compounds, aniline-based compounds, silane-based compounds, thiophene-based compounds, pyrrole-based compounds, florene-based compounds, porphyrin-based compounds, quinacridon-based compounds, phthalocyanine-based compounds, naphthalocyanine-based compounds, and benzidine-based compounds.

5. The hole transport material as claimed in claim 1, wherein the hold transport material contains a poly(thiophene/styrenesulfonate)-based compound as its major component, and wherein when the hole transport material is dissolved or dispersed in a liquid so that its concentration thereof becomes 2.0 wt %, the liquid contains nonionic impurities having a molecular weight of 5,000 or less, but an amount of the nonionic impurities contained therein is six or less with respect to 1,000 styrene units.

6. The hole transport material as claimed in claim 5, wherein the number of the nonionic impurities and the number of the styrene units are measured from areas of peaks in a spectrum obtained by an ¹H-NMR analysis for the liquid.

7. The hole transport material as claimed in claim 5, wherein the poly(thiophene/styrenesulfonate) -based compound has a weight ratio of thiopene to styrenesulfonate which is in the range of 1:5 to 1:50.

8. The hold transport material as claimed in claim 1, wherein the volume resistivity of the hole transport material is 10 Ω·cm or larger.

9. A layer having the function of transporting holes and provided in an organic EL device, wherein the layer is characterized by containing nonionic impurities having a molecular weight of 5,000 or less, but an amount of the nonionic impurities is 2,000 ppm or less.

10. A layer having the function of transporting holes and provided in an organic EL device, the layer being formed from a hole transport material containing poly(thiophene/styrenesulfonate)-based compound as its major component, wherein the layer contains nonionic impurities having a molecular weight of 5,000 or less, but an amount of the nonionic impurities contained therein is 6 or less with respect to 1000 styrene units.

11. The layer as claimed in claim 10, wherein the number of the nonionic impurities and the number of the styrene units are measured from areas of peaks in a spectrum obtained by an ¹H-NMR analysis for the layer.

12. A layer having the function of transporting holes and provided in an organic EL device, the layer being characterized by being formed from a material containing the hole transport material described in claim 1 as its major component.

13. An organic EL device having a layer described in claim 9.

14. A method of manufacturing a hole transport material described in claim 1, the method comprising the steps of:
preparing absolution or dispersion liquid in which the hole transport material is dissolved or dispersed in a solvent or a dispersion medium;
separating or eliminating nonionic impurities having a molecular weight of 5,000 or less using an eliminating means for separating or eliminating the nonionic impurities; and
removing the solvent or dispersion medium from the liquid, thereby refining the hole transport material.

15. The method of manufacturing a hole transport material as claimed in claim 14, wherein the eliminating means includes an ultrafiltration membrane.

16. A hole transport material to be used for a layer having the function of transporting holes in an organic EL device, the hole transport material being characterized in that when the hole transport material is dissolved or dispersed in a liquid so that its concentration becomes 2.0 wt %, the liquid contains anionic impurities, cationic impurities and nonionic impurities having a molecular weight of 5,000 or less, but amounts of the anionic impurities, cationic impurities and nonionic impurities contained therein are 30 ppm or less, 30 ppm or less and 40 ppm or less, respectively.

17. The hole transport material as claimed in claim 16, wherein when the hole transport material is dissolved or dispersed in a liquid so that its concentration becomes 2.0 wt %, the total amount of the anionic impurities, cationic impurities and nonionic impurities contained therein is 90 ppm or less.

18. The hole transport material as claimed in claim 16, wherein the anionic impurities include at least one of sulfate ion, formate ion, oxalate ion and acetate ion.

19. The hole transport material as claimed in claim 16, wherein the cationic impurities mainly include metal ion.

20. The hole transport material as claimed in claim 19, wherein the metal ion includes at least one kind of metal ions of metals belonging to Ia group, IIa group, VIa group, VIIa group, VIII group and IIb group of the periodic table.

21. The hole transport material as claimed in claim 16, wherein the nonionic impurities mainly include those which are formed and/or mixed when synthesizing the hole transport material.

22. The hole transport material as claimed in claim 16, wherein the nonionic impurities include at least one of polyalcohol and heterocyclic aromatic compound.

23. The hold transport material as claimed in claim 16, wherein the volume resistivity of the hole transport material is 10 Ω·cm or larger.

24. The hole transport material as claimed in claim 16, wherein the hole transport material includes at least one selected from the group comprising thiophene/styrenesulfonate-based compounds, arylcycloalkane-based compounds, arylamine-based compounds, phenylenediamine-based compounds, carbazole-based compounds, stilbene-based compounds, oxazole-based compounds, triphenylmethane-based compounds, pyrazoline-based compounds, benzine-based compounds, triazole-based compounds, imidazole-based compounds, oxadiazole-based compounds, anthracene-based compounds, fluorenone-based compounds, aniline-based compounds, silane-based compounds, thiophene-based compounds, pyrrole-based compounds, florene-based compounds, porphyrin-based compounds, quinacridon-based compounds, phthalocyanine-based compounds, naphthalocyanine-based compounds, and benzidine-based compounds.

25. The hole transport material as claimed in claim 16, wherein the hold transport material contains a poly(thiophene/styrenesulfonate)-based compound as its major component.

26. The hole transport material as claimed in claim 25, wherein the poly(thiophene/styrenesulfonate)-based compound has a weight ratio of thiopene to styrenesulfonate which is in the range of 1:5 to 1:50

27. A layer having the function of transporting holes and provided in an organic EL device, wherein the layer is characterized by containing anionic impurities, cationic impurities and nonionic impurities having a molecular weight of 5,000 or less, but amounts of the anionic impurities, cationic impurities and nonionic impurities are 1,500 ppm or less, 1500 ppm or less and 2,000 ppm or less, respectively.

28. The layer as claimed in claim 27, wherein the total amount of the anionic impurities, cationic impurities and nonionic impurities is 4,500 ppm or less.

29. A layer having the function of transporting holes and provided in an organic EL device, the layer being characterized by being formed from a material containing the hole transport material described in claim 1 as its major component.

30. An organic EL device having a layer described in claim 27.

31. A method of manufacturing a hole transport material described in claim 16, the method comprising the steps of:
preparing a solution or dispersion liquid in which the hole transport material is dissolved or dispersed in a solvent or a dispersion medium;
separating or eliminating anionic impurities, cationic impurities and nonionic impurities having a molecular weight of 5,000 or less using a first eliminating means for separating or eliminating the anionic impurities, a second eliminating means for separating or eliminating the cationic impurities, and a third eliminating means for separating or eliminating the nonionic impurities at substantially the same time or successively; and
removing the solvent or dispersion medium from the liquid, thereby refining the hole transport material.

32. The method of manufacturing a hole transport material as claimed in claim 31, wherein the third eliminating means includes an ultrafiltration membrane.
